(19) United States
(12) Patent Application Publication
(10) Pub. No.: US 2025/0070075 A1
(43) Pub. Date: Feb. 27, 2025

(54) PACKAGE STRUCTURE

(71) Applicant: Advanced Semiconductor Engineering, Inc., Kaohsiung (TW)

(72) Inventors: Chi-Yang CHIANG, Kaohsiung (TW); Man-Wen TSENG, Kaohsiung (TW); Chien-Ching CHEN, Kaohsiung (TW)

(73) Assignee: Advanced Semiconductor Engineering, Inc., Kaohsiung (TW)

(21) Appl. No.: 18/237,880

(22) Filed: Aug. 24, 2023

(51) Int. Cl. H01L 23/00; H01L 23/498; H01L 23/538

(52) U.S. Cl. CPC H01L 24/46; H01L 23/49816; H01L 23/5381; H01L 2224/46

(57) ABSTRACT

A package structure includes a wiring structure, a first electronic device and a reinforcement structure. The first electronic device is disposed over the top surface of the wiring structure, and has a bottom surface facing the top surface of the wiring structure. The first electronic device includes a plurality of first wires. The reinforcement structure is disposed over the top surface of the wiring structure, and includes a plurality of second wires directly contacting the plurality of first wires to reduce a variation of an elevation of the bottom surface of the first electronic device with respect to the top surface of the wiring structure.

### BACKGROUND

### 1. Field of the Disclosure

The present disclosure relates to a package structure, and to a package structure including an electronic device.

### 2. Description of the Related Art

Along with the rapid development in electronics industry and the progress of semiconductor processing technologies, semiconductor package structures are integrated with an increasing number of electronic components or electronic devices to achieve improved electrical performance and additional functions. Accordingly, a warpage of the semiconductor package structure may occur during the thermal process due to CTE mismatch between various materials. Since a rigidity or stiffness of the semiconductor package structure is relatively low, a crack may be formed at the top surface of the semiconductor package structure or in the protection material, and then extend or grow into the interior of the semiconductor package structure. If the crack reaches the semiconductor package structure, the circuit layer in the semiconductor package structure may be damaged or broken, which may result in an open circuit and render the semiconductor package structure inoperative. Thus, a yield of the semiconductor package structure may decrease.

### SUMMARY

In some embodiments, a package structure includes a wiring structure, a first electronic device and a reinforcement structure. The first electronic device is disposed over the top surface of the wiring structure, and has a bottom surface facing the top surface of the wiring structure. The first electronic device includes a plurality of first wires. The reinforcement structure is disposed over the top surface of the wiring structure, and includes a plurality of second wires directly contacting the plurality of first wires to reduce a variation of an elevation of the bottom surface of the first electronic device with respect to the top surface of the wiring structure.

In some embodiments, a package structure includes a bridge interposer, a first electronic device and a second electronic device. The first electronic device is disposed over the bridge interposer. The second electronic device is disposed over the bridge interposer, and is communicated with the first electronic device through the bridge interposer. The bridge interposer includes a first pad, a second pad, a plurality of first wires disposed on the first pad and a plurality of second wires disposed on the second pad. The first pad is electrically connected to the first electronic device through the plurality of first wires. The second pad is electrically connected to the second electronic device through the plurality of second wires.

In some embodiments, a package structure includes a wiring structure, a first electronic device and a solder material. The first electronic device is disposed over the wiring structure, and includes a first contact, a second contact, a plurality of wires disposed on the first contact and a bump disposed on the second contact. The solder material is electrically connected to the bump.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a package structure according to some embodiments of the present disclosure.

FIG. 2 illustrates a partially enlarged view of a region “A” in FIG. 1.

FIG. 2A illustrates a partially enlarged view of a region “A1” in FIG. 1.

FIG. 3 illustrates a cross-sectional view of a partially enlarged view of a package structure according to some embodiments of the present disclosure.

FIG. 4 illustrates a cross-sectional view of a partially enlarged view of a package structure according to some embodiments of the present disclosure.

FIG. 5 illustrates a cross-sectional view of a partially enlarged view of a package structure according to some embodiments of the present disclosure.

FIG. 6 illustrates a cross-sectional view of a package structure according to some embodiments of the present disclosure.

FIG. 7 illustrates a cross-sectional view of a package structure according to some embodiments of the present disclosure.

FIG. 8 illustrates a cross-sectional view of a package structure according to some embodiments of the present disclosure.

FIG. 9 illustrates a cross-sectional view of a package structure according to some embodiments of the present disclosure.

FIG. 10 illustrates a cross-sectional view of a package structure according to some embodiments of the present disclosure.

FIG. 11 illustrates a cross-sectional view of a package structure according to some embodiments of the present disclosure.

FIG. 12 illustrates a cross-sectional view of a package structure according to some embodiments of the present disclosure.

FIG. 13 illustrates a cross-sectional view of a package structure according to some embodiments of the present disclosure.

FIG. 14 illustrates a cross-sectional view of a package structure according to some embodiments of the present disclosure.

FIG. 15 illustrates a partially enlarged view of a region “B” in FIG. 14.

FIG. 16 illustrates a cross-sectional view of a package structure according to some embodiments of the present disclosure.

FIG. 17 illustrates a top view of a relative position between the first electronic device and the interposer.

FIG. 18 illustrates a partially enlarged view of a region “C” in FIG. 17.

FIG. 19 illustrates a cross-sectional view of a package structure according to some embodiments of the present disclosure.

FIG. 19A illustrates a partially enlarged view of a region “D” in FIG. 19.

FIG. 20 illustrates a cross-sectional view of a package structure according to some embodiments of the present disclosure.

FIG. 20A illustrates a partially enlarged view of a region “E” in FIG. 20.

FIG. 21 illustrates one or more stages of an example of a method for manufacturing a package structure according to some embodiments of the present disclosure.

FIG. 22 illustrates one or more stages of an example of a method for manufacturing a package structure according to some embodiments of the present disclosure.

FIG. 23 illustrates one or more stages of an example of a method for manufacturing a package structure according to some embodiments of the present disclosure.

FIG. 24 illustrates one or more stages of an example of a method for manufacturing a package structure according to some embodiments of the present disclosure.

FIG. 25 illustrates one or more stages of an example of a method for manufacturing a package structure according to some embodiments of the present disclosure.

FIG. 26 illustrates one or more stages of an example of a method for manufacturing a package structure according to some embodiments of the present disclosure.

FIG. 27 illustrates one or more stages of an example of a method for manufacturing a package structure according to some embodiments of the present disclosure.

FIG. 28 illustrates one or more stages of an example of a method for manufacturing a package structure according to some embodiments of the present disclosure.

FIG. 29 illustrates one or more stages of an example of a method for manufacturing a package structure according to some embodiments of the present disclosure.

FIG. 30 illustrates one or more stages of an example of a method for manufacturing a package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

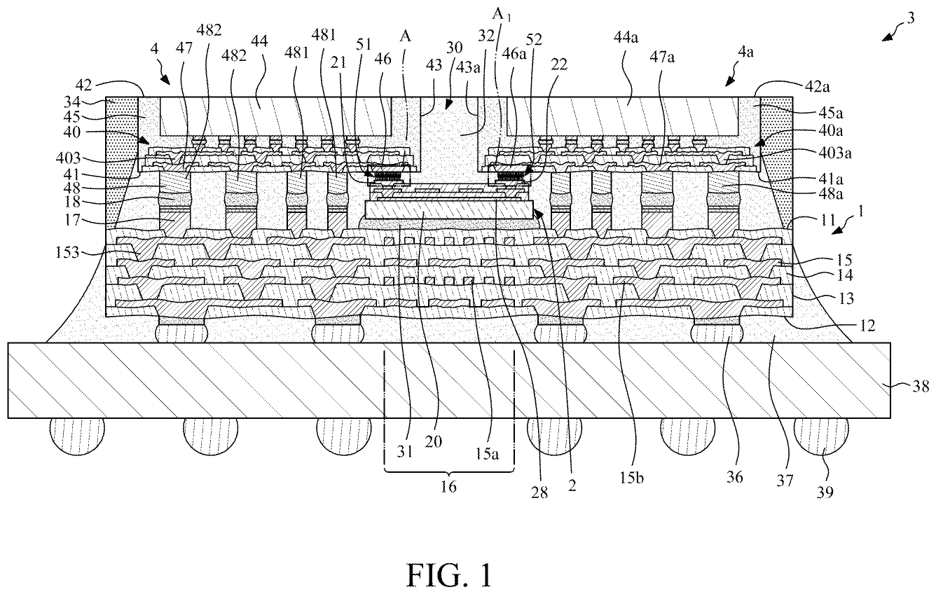

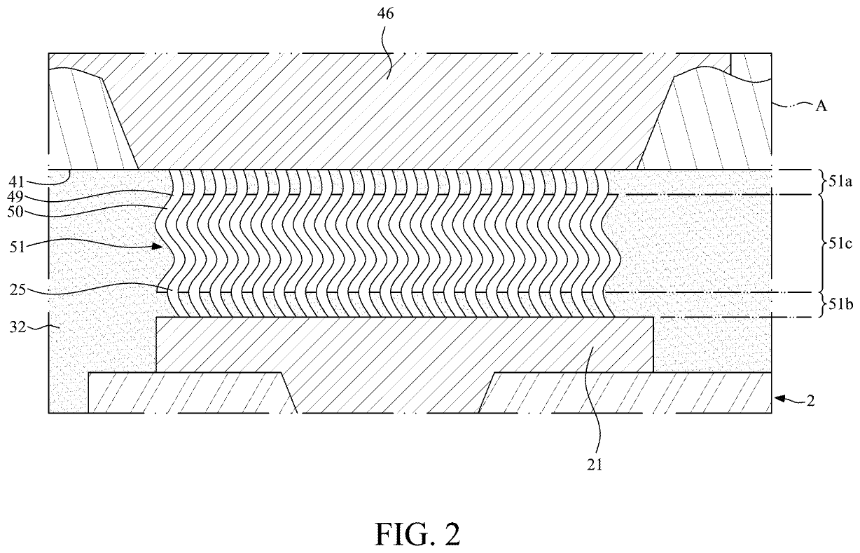

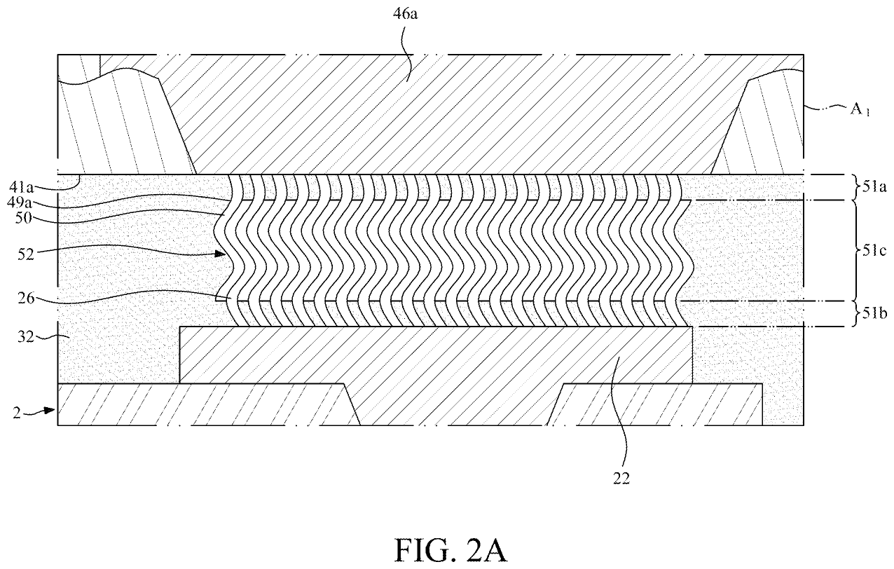

FIG. 1 illustrates a cross-sectional view of a package structure 3 according to some embodiments of the present disclosure. FIG. 2 illustrates a partially enlarged view of a region “A” in FIG. 1. FIG. 2A illustrates a partially enlarged view of a region “A₁” in FIG. 1. The package structure 3 may include a wiring structure 1, a first electronic device 4, a second electronic device 4a, an interposer 2, a first restriction structure 51, a second restriction structure 52, a first protection material 32, a second protection material 34 and a plurality of solder materials 36. As shown in FIG. 1, the package structure 3 may be attached to a substrate 38. In some embodiments, the substrate 38 may include a two-layer substrate which includes a core layer and a conductive material and/or structure disposed on an upper surface (or a top surface) and a lower surface (or a bottom surface) of the core layer. The conductive material and/or structure may include a plurality of traces. The substrate 38 may include one or more conductive pads (not shown) in proximity to, adjacent to, or embedded in and exposed by an upper surface and/or a lower surface of the substrate 38.

As shown in FIG. 1, the wiring structure 1 may have a first surface 11 (e.g., a top surface or an upper surface), a second surface 12 (e.g., a bottom surface or a lower surface) opposite to the first surface 11, a lateral surface 13 extending between the first surface 11 and the second surface 12, and a high density region 16 (or a fine line region) between the first electronic device 4 and the second electronic device 4a. The wiring structure 1 may include at least one dielectric layer 14, at least one circuit layer 15 in contact with the dielectric layer 14, and a plurality of protrusion contacts 17 (e.g., protrusion pads, or bumps). The circuit layer 15 and the dielectric layer 14 may have curved surfaces. For example, the wiring structure 1 may include five dielectric layers and four circuit layers. A material of the circuit layer 15 may include, for example, copper, another conductive metal, or an alloy thereof. A material of the dielectric layer 14 may include an insulating material, a passivation material, a dielectric material or a solder resist material, such as, for example, a benzocyclobutene (BCB) based polymer or a polyimide (PI). In some embodiments, the dielectric layer 14 may be made of a photoimageable material. In some embodiments, the circuit layers 15 may be embedded in the dielectric layers 14, and exposed from the first surface 11 and the second surface 12.

The circuit layer 15 may be a redistribution layer (RDL). Further, the circuit layer 15 may include an interconnection portion 15a and a periphery portion 15b. The interconnection portion 15a is located in the high density region 16, and the periphery portion 15b is located outside the high density region 16 (e.g., a low density region). For example, the second electronic device 4a may be electrically connected to the first electronic device 4 through the interconnection portion 15a of the circuit layer 15. The second electronic device 4a and the first electronic device 4 may be electrically connected to the solder materials 36 on the second surface 12 of the wiring structure 1 through the periphery portion 15b of the circuit layer 15. A line width/line space (L/S) of the traces of the interconnection portion 15a may be less than an L/S of the traces of the periphery portion 15b. For example, an L/S of the traces of the interconnection portion 15a may be less than or equal to about 5 μm/about 5 μm, or less than or equal to about 2 μm/about 2 μm, or less than or equal to about 0.8 μm/about 0.8 μm. An L/S of the traces of the periphery portion 15b may be less than or equal to about 10 μm/about 10 μm, or less than or equal to about 7 μm/about 7 μm, or less than or equal to about 5 μm/about 5 μm.

A via portion 153 of the circuit layer 15 may extend through a dielectric layer 14 to electrically connect two adjacent circuit layers 15. In some embodiments, the via portion 153 may extend from the periphery portion 15b, and they may be formed concurrently and integrally. In some embodiments, the via portion 153 may taper downward.

The protrusion contacts 17 may be disposed on and protrude from the topmost dielectric layer 14 of the wiring structure 1. The protrusion contacts 17 may be disposed on and protrude from the first surface 11 of the wiring structure 1, and extend through the topmost dielectric layer 14 to electrically connect the circuit layer 15.

The first electronic device 4 and the second electronic device 4a may be disposed over the first surface 11 of the wiring structure 1. The first electronic device 4 and the second electronic device 4a may be disposed adjacent to the first surface 11 of the wiring structure 1 side by side, and may be electrically connected to the circuit layer 15 of the wiring structure 1. The first electronic device 4 and the second electronic device 4a may be disposed over the bridge interposer 2. The second electronic device 4a may be communicated with the first electronic device 4 through the bridge interposer 2. A gap 30 may be formed between the lateral surface 43 of the first electronic device 4 and the lateral surface 43a of the second electronic device 4a. The first electronic device 4 may be a semiconductor device such as an application specific integrated circuit (ASIC) die, or a semiconductor package, or a chip. In some embodiments, the first electronic device 4 may have a first surface 41 (e.g., a lower surface or a bottom surface) facing the top surface 11 of the wiring structure 1, a second surface 42 (e.g., an upper surface or a top surface) opposite to the first surface 41, and a lateral surface 43 extending between the first surface 41 and the second surface 42.

In some embodiments, the first electronic device 4 may include a first patterned circuit structure 40, a first die 44, a protection material 45 and a plurality of first upper wires 49. The first upper wires 49 may be also referred to as “first wires 49” or “wires 49”. The first patterned circuit structure 40 may include at least one dielectric layer, at least one circuit layer in contact with the dielectric layer, and a plurality of protrusion contacts (e.g., protrusion pads). The circuit layer and the dielectric layer may have curved surfaces. A via portion 403 of the circuit layer may extend through a dielectric layer to electrically connect two adjacent circuit layers. In some embodiments, the via portion 403 of the first patterned circuit structure 40 may taper downward. In addition, the first die 44 may include a plurality of bumps electrically connected and physically connected to the protrusion contacts of the first patterned circuit structure 40. The protection material 45 (e.g., underfill or molding compound) may cover the bumps and the protrusion contacts, and may encapsulate the first die 44.

In some embodiments, the first patterned circuit structure 40 of the first electronic device 4 may further include a first contact 46 (e.g., a bottom portion of a first via portion) and a plurality of bonding contacts 47 (e.g., a bottom portion of a bonding via portion) exposed from the first surface 41 of the first electronic device 4. The bonding contact 47 may be also referred to as “a second contact 47”. Each of the first contact 46 and the bonding contacts 47 may be an electrical contact. The first contact 46 of the first patterned circuit structure 40 of the first electronic device 4 is an outermost contact. The first contact 46 is closer to the interposer 2 than the bonding contact 47 is. The first electronic device 4 may further include a plurality of first electrical connectors 48 (such as bumps, studs, pillars or posts) disposed on the bonding contacts 47 (or second contacts 47). The first electrical connectors 48 may be electrically connected and physically connected to the protrusion contacts 17 of the wiring structure 1 through a plurality of re-flowable materials 18 (e.g., solder materials 18). Thus, the re-flowable material 18 may be electrically connected to the first electronic device 4 and the wiring structure 1. The first electronic device 4 may be electrically connected to the wiring structure 1 through the re-flowable material 18 (e.g., solder material 18). The re-flowable material 18 (e.g., solder material 18) may be electrically connected to the first electrical connectors 48 (or bumps 48). In some embodiments, the first electrical connectors 48 may include a plurality of first bumps 481 and a plurality of second bumps 482. A width of the first bump 481 may be less than a width of the second bump 482. A pitch or gap between the first bumps 481 may be less than a pitch or gap between the second bumps 482. The first electronic device 4 may be electrically connected to the second electronic device 4a through the wires 49. The first electronic device 4 may be electrically connected to the wiring structure 1 through the re-flowable material 18 (e.g., solder material 18). The wires 49 may be closer to the second electronic device 4a than the first electrical connector 48 (or the bump 48) is. A length of the first electrical connector 48 (or the bump 48) may be greater than a length of one of the wires 49.

The second electronic device 4a may be a semiconductor device such as a high bandwidth memory (HBM) die, or a semiconductor package, or a chip. In some embodiments, the second electronic device 4a may have a first surface 41a (e.g., a lower surface or a bottom surface) facing the top surface 11 of the wiring structure 1, a second surface 42a (e.g., an upper surface of a top surface) opposite to the first surface 41a, and a lateral surface 43a extending between the first surface 41a and the second surface 42a.

In some embodiments, the second electronic device 4a may include a second patterned circuit structure 40a, a second die 44a, a protection material 45a and a plurality of first upper wires 49a. The first upper wires 49a may be also referred to as “third wires 49a” or “wires 49a”. The second patterned circuit structure 40a may include at least one dielectric layer, at least one circuit layer in contact with the dielectric layer, and a plurality of protrusion contacts (e.g., protrusion pads). The circuit layer and the dielectric layer may have curved surfaces. A via portion 403a of the circuit layer may extend through a dielectric layer to electrically connect two adjacent circuit layers. In some embodiments, the via portion 403a of the second patterned circuit structure 40a may taper downward. In addition, the second die 44a may include a plurality of bumps electrically connected and physically connected to the protrusion contacts of the second patterned circuit structure 40a. The protection material 45a (e.g., underfill or molding compound) may cover the bumps and the protrusion contacts, and may encapsulate the second die 44a.

In some embodiments, the second patterned circuit structure 40a of the second electronic device 4a may further include a first contact 46a and a plurality of bonding contacts 47a exposed from the first surface 41a of the second electronic device 4a. The first contact 46a of the second patterned circuit structure 40a of the second electronic device 4a is an outermost contact. The first contact 46a is closer to the interposer 2 than the bonding contact 47a is. The second electronic device 4a may further include a plurality of second electrical connectors 48a (such as bumps, studs, pillars or posts) disposed on the bonding contacts 47a. The second electrical connectors 48a may be electrically connected and physically connected to the protrusion contacts 17 of the wiring structure 1 through the re-flowable materials 18 (e.g., solder materials 18).

The interposer 2 may be a bridge interposer 2 (e.g., a bridge die) or a reinforcement structure 2, and may include a base portion 20, a bridge interconnector 28 (or a bridge circuit layer 28) and a plurality of contacts (e.g., a first contact 21 and a third contact 22) disposed adjacent to a top surface of the interposer 2. The first contact 21 may be a first pad 21. The third contact 22 may be a second pad 22. The base portion 20 may include a main body, at least one circuit layer (e.g., the bridge interconnector 28 or bridge circuit layer 28) and at least one passivation layer disposed on a top surface of the main body. The main body may include a silicon material. The contacts (e.g., the first contact 21 and the third contact 22) may be pads protruded from the passivation layer. The first contact 21 may be electrically connected to the third contact 22 through the bridge interconnector 28 (or bridge circuit layer 28). Thus, the bridge interconnector 28 (or bridge circuit layer 28) may be configured to bridge communication between the first electronic device 4 and the second electronic device 4a. A bottom surface of the interposer 2 may be attached or adhered to the first surface 11 of the wiring structure 1 through an adhesion layer 31.

The reinforcement structure 2 (or the bridge interposer 2) may be disposed between the top surface 11 of the wiring structure 1 and the first electronic device 4, and disposed between the top surface 11 of the wiring structure 1 and the second electronic device 4a. The wiring structure 1 may be disposed under the bridge interposer 2. A portion (e.g., left portion) of the interposer 2 (e.g., the reinforcement structure 2 or the bridge interposer 2) may be disposed in a space between the first electronic device 4 and the wiring structure 1. Thus, the first electronic device 4 may be disposed over the interposer 2, and at least a portion of the first electronic device 4 may be vertically non-overlapping with the interposer 2. The first electronic device 4 may be partially overlapping with the interposer 2. Another portion (e.g., right portion) of the interposer 2 may be disposed in a space between the second electronic device 4a and the wiring structure 1. Thus, the second electronic device 4a may be disposed over the interposer 2, and at least a portion of the second electronic device 4a may be vertically non-overlapping with the interposer 2. The second electronic device 4a may be partially overlapping with the interposer 2. A portion of the first electronic device 4 may be vertically non-overlapping with the bridge interposer 2, and a portion of the second electronic device 4a may be vertically non-overlapping with the bridge interposer 2.

The reinforcement structure 2 (or the bridge interposer 2) may include a plurality of first lower wires 25, 26. The first lower wires 25 may be also referred to as “first wires 25” or “second wires 25”. The first lower wires 26 may be also referred to as “second wires 26” or “fourth wires 26”. The first wires 25 may be disposed on the first pad 21. The second wires 26 may be disposed on the second pad 22. The first pad 21 may be electrically connected to the first electronic device 4 through the first wires 25. The second pad 22 may be electrically connected to the second electronic device 4a through the plurality of second wires 26.

The first lower wires 25 (or the second wires 25) may be configured to directly contact the first wires 49 of the first electronic device 4 so as to reduce a variation of an elevation of the first electronic device 4 with respect to the top surface 11 of the wiring structure 1. For example, the contact assembly of the second wires 25 and the first wires 49 may reduce a variation of an elevation of the first surface 41 (e.g., the bottom surface) of the first electronic device 4 with respect to the top surface 11 of the wiring structure 1. Thus, the contact assembly of the second wires 25 and the first wires 49 may reduce a difference between a maximum vertical distance between a first region of the first surface 41 of the first electronic device 4 with respect to the top surface 11 of the wiring structure 1 and a minimum vertical distance between a second region of the first surface 41 of the first electronic device 4 with respect to the top surface 11 of the wiring structure 1. Similarly, the first lower wires 26 (or the fourth wires 26) may be configured to directly contact the third wires 49a of the second electronic device 4a so as to reduce a variation of an elevation of the second electronic device 4a with respect to the top surface 11 of the wiring structure 1. For example, the contact assembly of the fourth wires 26 and the third wires 49a may reduce a variation of an elevation of the first surface 41a (e.g., the bottom surface) of the second electronic device 4a with respect to the top surface 11 of the wiring structure 1. Thus, the contact assembly of the fourth wires 26 and the third wires 49a may reduce a difference between a maximum vertical distance between a first region of the first surface 41a of the second electronic device 4a with respect to the top surface 11 of the wiring structure 1 and a minimum vertical distance between a second region of the first surface 41a of the second electronic device 4a with respect to the top surface 11 of the wiring structure 1.

In some embodiments, the first lower wires 25 (or the second wires 25) and the first upper wires 49 (or the first wires 49) may be entangled with each other and may be joined tightly through the clamping force and friction force therebetween. Since the first lower wires 25 and the first upper wires 49 may not be melted during a reflow process, the combination of the first lower wires 25 and the first upper wires 49 may be configured to reduce the variation of an elevation of the first surface 41 (e.g., the bottom surface) of the first electronic device 4 with respect to the top surface 11 of the wiring structure 1 during the reflow process. In addition, the first lower wires 26 (or the fourth wires 26) and the third wires 49a may be entangled with each other and may be joined tightly through the clamping force and friction force therebetween. Since the first lower wires 26 (or the fourth wires 26) and the third wires 49a may not be melted during the reflow process, the combination of the first lower wires 26 (or the fourth wires 26) and the third wires 49a may be configured to reduce the variation of an elevation of the first surface 41a of the second electronic device 4a with respect to the top surface 11 of the wiring structure 1 during the reflow process.

The first restriction structure 51 may be disposed between the interposer 2 and the first electronic device 4. The first restriction structure 51 may be an electrically connecting structure, a conductive structure, or an electrical path. The first restriction structure 51 may connect the first contact 21 of the interposer 2 and the first contact 46 of the first electronic device 4, and may be configured to restrict or inhibit a warpage of the package structure 3 during a thermal cycle. The second restriction structure 52 may be disposed between the interposer 2 and the second electronic device 4a. The second restriction structure 52 may be an electrically connecting structure, a conductive structure, or an electrical path. The second restriction structure 52 may connect the third contact 22 of the interposer 2 and the first contact 46a of the second electronic device 4a, and may be configured to restrict a warpage of the package structure 3 during a thermal cycle.

The first protection material 32 may be disposed in a first space between the first electronic device 4 and the wiring structure 1 and a second space between the second electronic device 4a and the wiring structure 1 so as to cover and protect the joints formed by the first electrical connectors 48, the protrusion contacts 17 and the re-flowable materials 18 (e.g., solder materials 18), and the joints formed by the second electrical connectors 48a, the protrusion contacts 17 and the re-flowable materials 18 (e.g., solder materials 18). The first protection material 32 may be an encapsulant such as an underfill. In addition, the first protection material 32 may cover the interposer 2, and may further extend into the gap 30 between the lateral surface 43 of the first electronic device 4 and the lateral surface 43a of the second electronic device 4a. The first protection material 32 may encapsulate the interposer 2, the first electronic device 4 and the second electronic device 4a. Thus, a portion of the first protection material 32 may be disposed between the interposer 2 and the first electronic device 4, and between the interposer 2 and the second electronic device 4a.

The second protection material 34 may cover at least a portion of the first surface 11 of the wiring structure 1, at least a portion of the first electronic device 4 and at least a portion of the second electronic device 4a. A material of the second protection material 34 may be an encapsulant such as a molding compound with or without fillers. The second protection material 34 may encapsulate the interposer 2, the first electronic device 4, the second electronic device 4a and the first protection material 32. A top surface of the second protection material 34, a second surface 42 of the first electronic device 4, a second surface 42a of the second electronic device 4a and a top surface of the first protection material 32 in the gap 30 may be substantially coplanar with each other. However, in other embodiments, the top surface of the first protection material 32 in the gap 30 may be recessed from the second surface 42 of the first electronic device 4 and the second surface 42a of the second electronic device 4a. Thus, a portion of the second protection material 34 may extend into the gap 30. In addition, a lateral surface of the second protection material 34 may be substantially coplanar with the lateral surface 13 of the wiring structure 1.

The solder materials 36 (e.g., solder balls) may be disposed adjacent to the second surface 12 of the wiring structure 1 for external connection. In some embodiments, the solder materials 36 (e.g., solder balls) may be disposed on the bottom bumps protruding from the second surface 12 of the wiring structure 1. For example, the package structure 3 may be attached to the substrate 38 through the solder materials 36. The third protection material 37 (e.g., underfill) may cover a portion of the lateral surface 13 of the wiring structure 1, the solder materials 36 and the upper surface of the substrate 38. A plurality of solder balls 39 may be disposed on the lower surface of the substrate 38.

As shown in FIG. 2, the first restriction structure 51 includes a plurality of wires 50 connecting to each other. The wires 50 may be metal nanowires or connecting wires. Each of the wires 50 may be in a solid cylindrical structure. The first restriction structure 51 may include an upper region 51a, a lower region 51b and an intermediate region 51c between the upper region 51a and the lower region 51b. A distribution density of the wires 50 in the intermediate region 51c is greater than a distribution density of the wires 50 in the upper region 51a and the lower region 51b. The wires 50 may form a high-density wire distribution region (i.e., the intermediate region 51c) and two low-density wire distribution regions (i.e., the upper region 51a and the lower region 51b). An amount of the wires 50 in the high-density wire distribution region (i.e., the intermediate region 51c) is greater than an amount of the wires 50 in the low-density wire distribution region (i.e., the upper region 51a and the lower region 51b).

The wires 50 of the first restriction structure 51 may include the first lower wires 25 (or the second wires 25) and the first upper wires 49 (or the first wires 49). The first lower wires 25 may be disposed on the first contact 21 of the interposer 2. The first upper wires 49 (or the wires 49) may be disposed on the first contact 46 of the first electronic device 4. The first lower wires 25 contact the first upper wires 49. The first lower wires 25 may insert into the spacing between the first upper wires 49. The first upper wires 49 may insert into the spacing between the first lower wires 25. The first lower wires 25 and the first upper wires 49 may be entangled with each other. Thus, the first lower wires 25 and the first upper wires 49 are joined tightly through the clamping force and friction force therebetween. Therefore, the combination of the first lower wires 25 and the first upper wires 49 may be configured to inhibit (or reduce) a shift between the first contact 21 of the interposer 2 and the first contact 46 of the first electronic device 4. In addition, the combination of the first lower wires 25 and the first upper wires 49 may be configured to inhibit (or reduce) a warpage of the first electronic device 4. In some embodiments, the first lower wires 25 may not contact the first contact 46 of the first electronic device 4. The first upper wires 49 may not contact the first contact 21 of the interposer 2.

As shown in FIG. 2A, the wires 50 of the second restriction structure 52 may include the first lower wires 26 (or the fourth wires 26) and the third wires 49a. The first lower wires 26 may be disposed on the third contact 22 of the interposer 2. The third wires 49a may be disposed on the first contact 46a of the second electronic device 4a. The first lower wires 26 contact the third wires 49a. The first lower wires 26 may insert into the spacing between the third wires 49a. The third wires 49a may insert into the spacing between the first lower wires 26. The first lower wires 26 and the third wires 49a may be entangled with each other. Thus, the first lower wires 26 and the third wires 49a are joined tightly through the clamping force and friction force therebetween. Therefore, the combination of the first lower wires 26 and the third wires 49a may be configured to inhibit (or reduce) a shift between the third contact 22 of the interposer 2 and the first contact 46a of the second electronic device 4a. In addition, the combination of the first lower wires 26 and the third wires 49a may be configured to inhibit (or reduce) a warpage of the second electronic device 4a. In some embodiments, the first lower wires 26 may not contact the first contact 46a of the second electronic device 4a. The third wires 49a may not contact the third contact 22 of the interposer 2.

In some embodiments, the interposer 2 may be also referred to as “a reinforcement structure 2”. The reinforcement structure 2 may be disposed in the first protection material 32 (e.g., an underfill), and may be configured to reduce a delamination between the first protection material 32 (e.g., the underfill) and the first electronic device 4, or a delamination between the first protection material 32 (e.g., the underfill) and the second electronic device 4a. The reinforcement structure 2 may include a base portion 20 and a plurality of wires 50. The first protection material 32 (e.g., the underfill) may extend into a space between the wires 50 (including, for example, the first lower wires 25 and the first upper wires 49). As shown in FIG. 2 and FIG. 2A, the first protection material 32 (e.g., the underfill) may encapsulate the first wires 25 and the second wires 26.

In some embodiments, the interposer 2 may be also referred to as “a fixing structure 2”. The re-flowable material 18 may be disposed between and electrically connecting the bonding contact 47 of the first electronic device 4 and the protrusion contact 17 of the wiring structure 1. The fixing structure 2 may be disposed between the wiring structure 1 and the first electronic device 4. The fixing structure 2 may include the base portion 20 and the first lower wires 25 disposed on or protruding from the base portion 20. The first electronic device 4 may include the first upper wires 49 disposed on or protruding from the first contact 46. The first upper wires 49 contacts the first lower wires 25. For example, the first upper wires 49 may engage with the first lower wires 25. The first upper wires 49 may insert into the space between the first lower wires 25, and the first lower wires 25 may insert into the space between the first upper wires 49. Because of the combination of the first upper wires 49 and the first lower wires 25, the fixing structure 2 may be configured to inhibit a shift between the bonding contact 47 of the first electronic device 4 and the protrusion contact 17 of the wiring structure 1 during a reflow process. In some embodiments, a transmission speed of a signal through the first lower wires 25 and the first upper wires 49 is higher than a transmission speed of a signal through the re-flowable material 18. That is, the first lower wires 25 and the first upper wires 49 may transmit high speed signal between the first electronic device 4 and the second electronic device 4a.

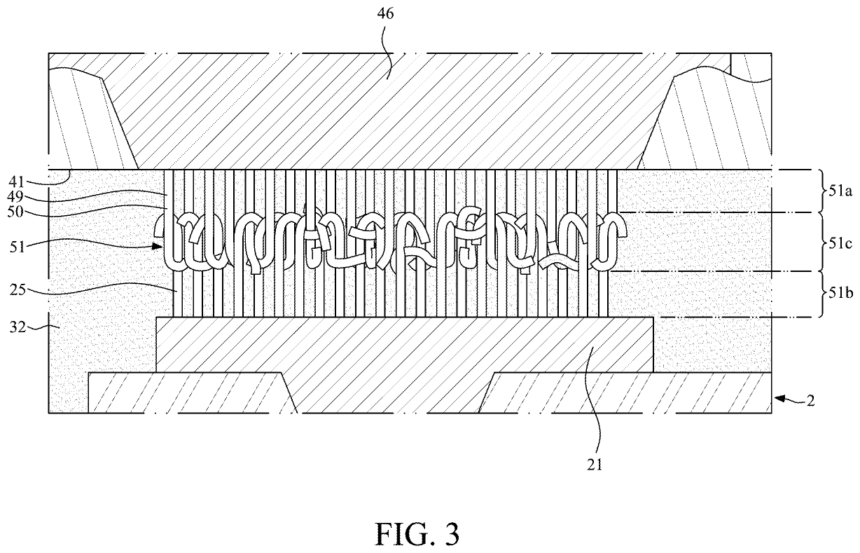

FIG. 3 illustrates a cross-sectional view of a partially enlarged view of a package structure according to some embodiments of the present disclosure. The structure of FIG. 3 is similar to the structure of FIG. 2, except the wires 50 (including, for example, the first lower wires 25 and the first upper wires 49) may be entangled with each other. Thus, the first lower wires 25 and the first upper wires 49 are joined tightly through the clamping force and friction force therebetween.

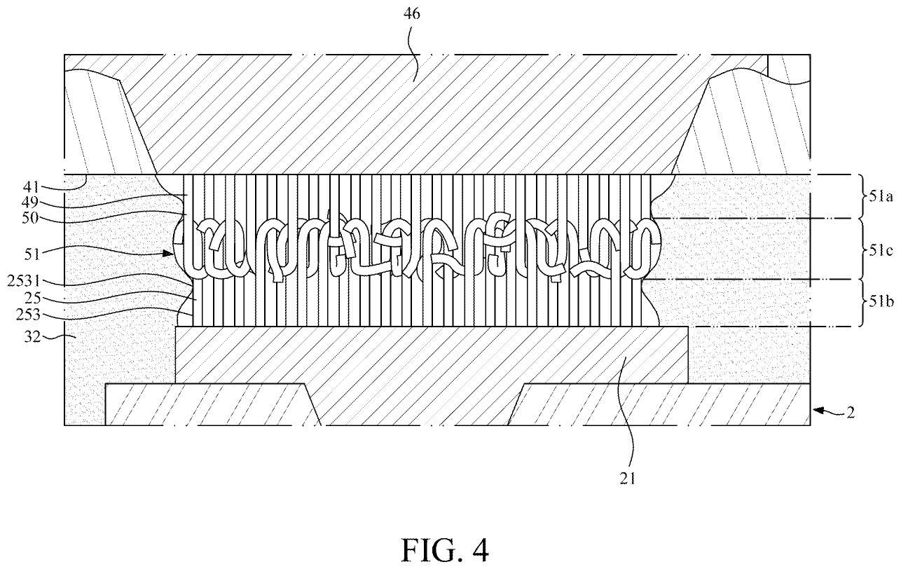

FIG. 4 illustrates a cross-sectional view of a partially enlarged view of a package structure according to some embodiments of the present disclosure. The structure of FIG. 4 is similar to the structure of FIG. 3, except that the first protection material 32 (e.g., the underfill) may not extend into the space between the wires 50 (including, for example, the first lower wires 25 and the first upper wires 49). The first protection material 32 (e.g., the underfill) may contact a portion 2531 of a lateral surface 253 of one of the first wires 25. The first protection material 32 (e.g., the underfill) may not extend to a gap or a space between the first lower wires 25 (e.g., the first wires 25). The underfill 32 may be spaced apart from the gap of the space between the first lower wires 25 (e.g., the first wires 25).

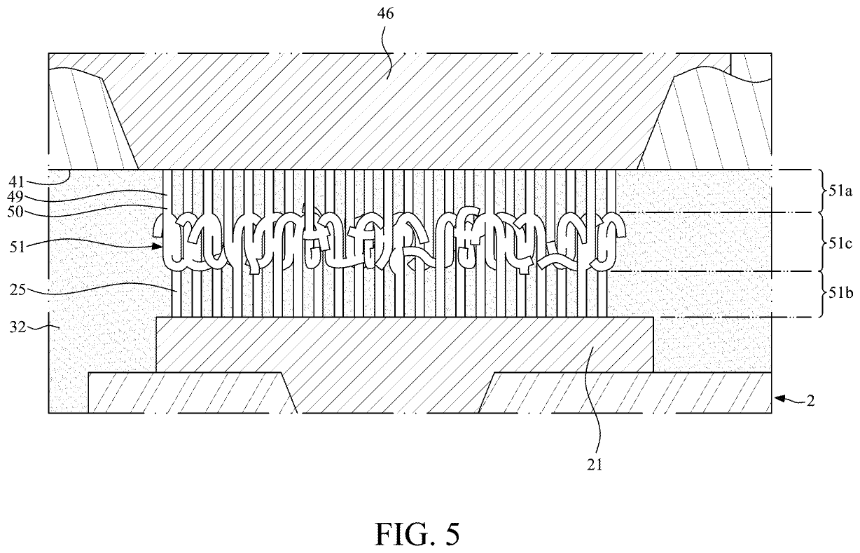

FIG. 5 illustrates a cross-sectional view of a partially enlarged view of a package structure according to some embodiments of the present disclosure. The structure of FIG. 5 is similar to the structure of FIG. 3, except that some of the wires 50 (including, for example, the first lower wires 25 and the first upper wires 49) may be fused together. Thus, some interfaces between the first lower wires 25 and the first upper wires 49 may be omitted.

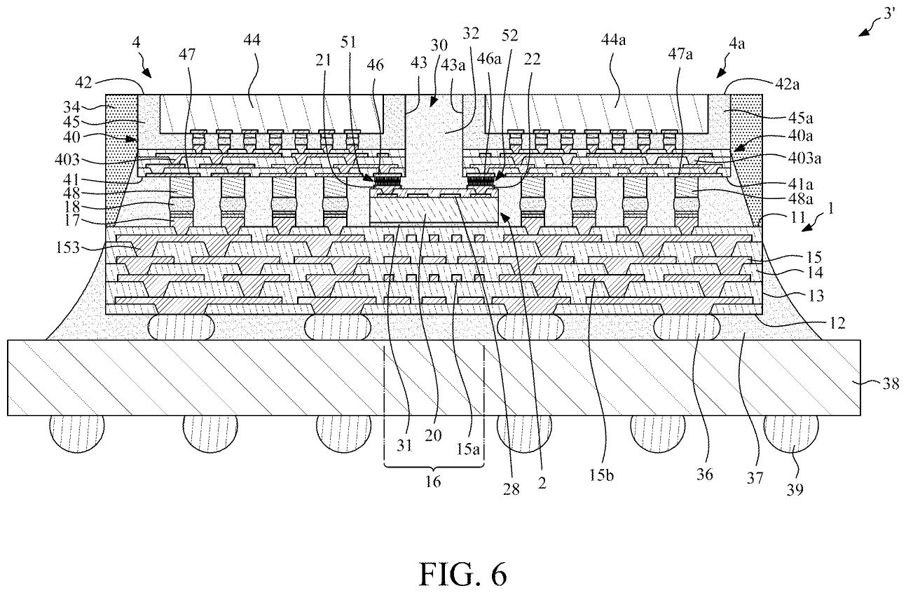

FIG. 6 illustrates a cross-sectional view of a package structure 3′ according to some embodiments of the present disclosure. The package structure 3′ of FIG. 6 may be similar to the package structure 3 of FIG. 1, and the differences therebetween may be described as follows. As shown in FIG. 6, the first contact 46 of the first electronic device 4 may be a first pad, and the bonding contact 47 of the first electronic device 4 may be a bonding pad. The first contact 46a of the second electronic device 4a may be a first pad, and the bonding contact 47a of the second electronic device 4a may be a bonding pad. In addition, the first electrical connectors 48 may have a consistent width and a consistent pitch or gap. The second electrical connectors 48a may have a consistent width and a consistent pitch or gap.

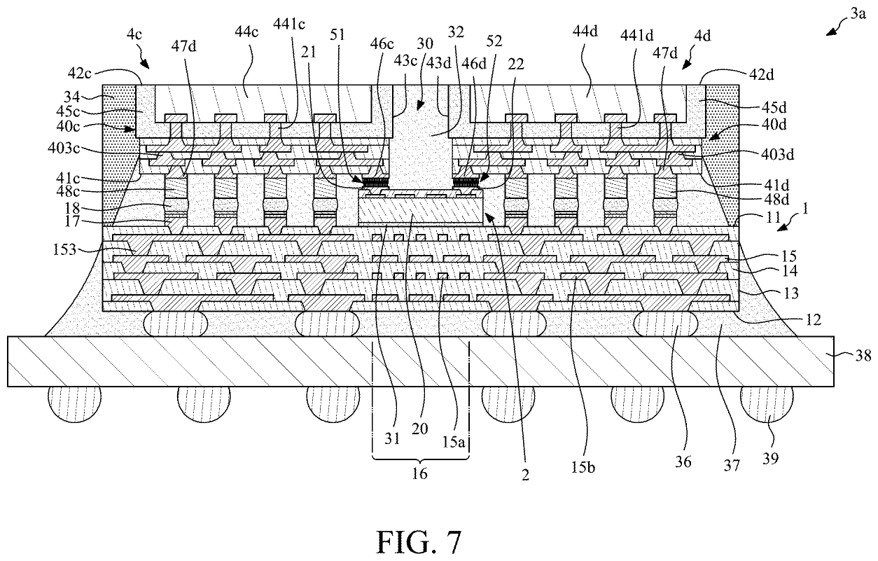

FIG. 7 illustrates a cross-sectional view of a package structure 3a according to some embodiments of the present disclosure. The package structure 3a of FIG. 7 is similar to the package structure 3 of FIG. 1 and the package structure 3′ of FIG. 6, except for the structures of the first electronic device 4c and the second electronic device 4d.

The first electronic device 4c may be a semiconductor device such as a semiconductor package. In some embodiments, the first electronic device 4c may have a first surface 41c (e.g., a bottom surface), a second surface 42c (e.g., a top surface) opposite to the first surface 41c, and a lateral surface 43c extending between the first surface 41c and the second surface 42c.

In some embodiments, the first electronic device 4c may include a first patterned circuit structure 40c, a first die 44c and a protection material 45c. The first patterned circuit structure 40c may include at least one dielectric layer, at least one circuit layer in contact with the dielectric layer and a plurality of electrical contacts. The circuit layer and the dielectric layer may have curved surfaces. A via portion 403c of the circuit layer may extend through a dielectric layer to electrically connect two adjacent circuit layers. In some embodiments, the via portion 403c of the first patterned circuit structure 40c may taper upward. In addition, the first die 44c may include a plurality of bumps 441c electrically connected and physically connected to the electrical contacts of the first patterned circuit structure 40c. The protection material 45c (e.g., underfill or molding compound) may cover the bumps 441c, and may encapsulate the first die 44c.

In some embodiments, the first patterned circuit structure 40c of the first electronic device 4c may further include a first contact 46c (e.g., a pad) and a plurality of bonding contacts 47 (e.g., a pad) exposed from the first surface 41c of the first electronic device 4c. The first contact 46c is closer to the interposer 2 than the bonding contact 47c is. The first electronic device 4c may further include a plurality of first electrical connectors 48c (such as bumps, studs, pillars or posts) disposed on the bonding contacts 47c. The first electrical connectors 48c may be electrically connected and physically connected to the protrusion contacts 17 of the wiring structure 1 through the re-flowable materials 18 (e.g., solder materials 18). The first contact 46c may be electrically connected and physically connected to the first contact 21 of the interposer 2 through the first restriction structure 51.

The second electronic device 4d may be a semiconductor device such as a semiconductor package. In some embodiments, the second electronic device 4d may have a first surface 41d (e.g., a bottom surface), a second surface 42d (e.g., a top surface) opposite to the first surface 41d, and a lateral surface 43d extending between the first surface 41d and the second surface 42d.

In some embodiments, the second electronic device 4d may include a second patterned circuit structure 40d, a second die 44d and a protection material 45d. The second patterned circuit structure 40d may include at least one dielectric layer, at least one circuit layer in contact with the dielectric layer, and a plurality of electrical contacts. The circuit layer and the dielectric layer may have curved surfaces. A via portion 403d of the circuit layer may extend through a dielectric layer to electrically connect two adjacent circuit layers. In some embodiments, the via portion 403d of the second patterned circuit structure 40d may taper upward. In addition, the second die 44d may include a plurality of bumps 441d electrically connected and physically connected to the electrical contacts of the second patterned circuit structure 40d. The protection material 45d (e.g., underfill or molding compound) may cover the bumps 441d, and may encapsulate the second die 44d.

In some embodiments, the second patterned circuit structure 40d of the second electronic device 4d may further include a first contact 46d and a plurality of bonding contacts 47d exposed from the first surface 41d of the second electronic device 4d. The first contact 46d is closer to the interposer 2 than the bonding contact 47d is. The second electronic device 4d may further include a plurality of second electrical connectors 48d (such as bumps, studs, pillars or posts) disposed on the bonding contacts 47d. The second electrical connectors 48da may be electrically connected and physically connected to the protrusion contacts 17 of the wiring structure 1 through the re-flowable materials 18 (e.g., solder materials 18). The first contact 46d may be electrically connected and physically connected to the third contact 22 of the interposer 2 through the second restriction structure 52.

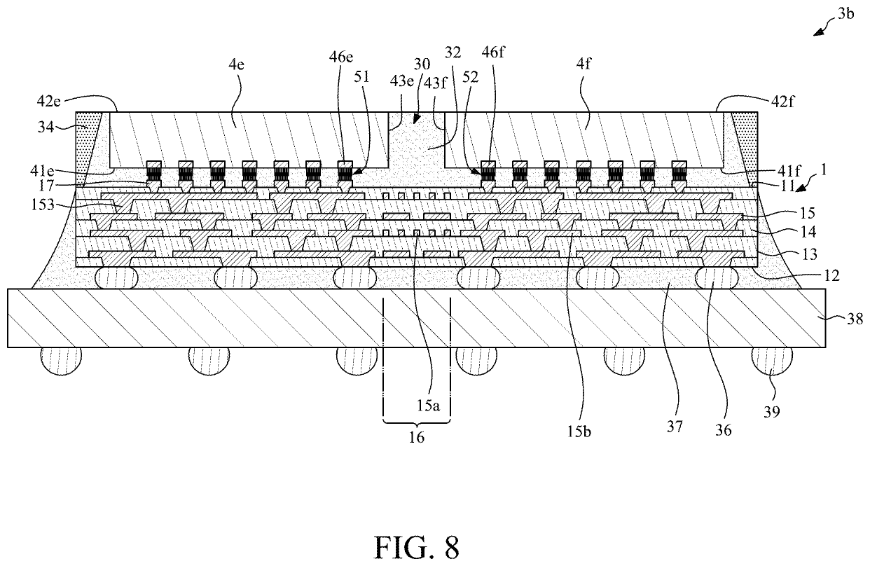

FIG. 8 illustrates a cross-sectional view of a package structure 3b according to some embodiments of the present disclosure. The package structure 3b may include a wiring structure 1, a first electronic device 4e, a second electronic device 4f, a first protection material 32, a second protection material 34 and a plurality of solder materials 36. As shown in FIG. 8, the package structure 3b may be attached to the substrate 38 through the solder materials 36. The wiring structure 1, the first protection material 32, the second protection material 34 and the solder materials 36 of FIG. 8 may be same as or similar to the wiring structure 1, the first protection material 32, the second protection material 34 and the solder materials 36 of FIG. 1.

The first electronic device 4e may be a semiconductor device such as an application specific integrated circuit (ASIC) die or a high bandwidth memory (HBM) die. In some embodiments, the first electronic device 4e may have a first surface 41e (e.g., a bottom surface), a second surface 42e (e.g., a top surface) opposite to the first surface 41e, and a lateral surface 43e extending between the first surface 41e and the second surface 42e. In some embodiments, the first electronic device 4e may further include a plurality of first contacts 46e (e.g., a plurality of pads) exposed from the first surface 41e of the first electronic device 4e. The first contacts 46e may be electrically connected and physically connected to the protrusion contacts 17 of the wiring structure 1 through the first restriction structure 51.

The second electronic device 4f may be a semiconductor device such as an application specific integrated circuit (ASIC) die or a high bandwidth memory (HBM) die. In some embodiments, the second electronic device 4f may have a first surface 41f (e.g., a bottom surface), a second surface 42f (e.g., a top surface) opposite to the first surface 41f, and a lateral surface 43f extending between the first surface 41f and the second surface 42f. In some embodiments, the second electronic device 4f may further include a plurality of first contacts 46f (e.g., a plurality of pads) exposed from the first surface 41f of the second electronic device 4f. The first contacts 46f may be electrically connected and physically connected to the protrusion contacts 17 of the wiring structure 1 through the second restriction structure 52. The first electronic device 4e and the second electronic device 4f may be not electrically connected and physically connected to the wiring structure 1 through any re-flowable contactors (e.g., solder materials). The first electronic device 4e and the second electronic device 4f may be electrically connected and physically connected to the wiring structure 1 solely through the connecting wires 50 (including, for example, the first lower wires 25 and the first upper wires 49).

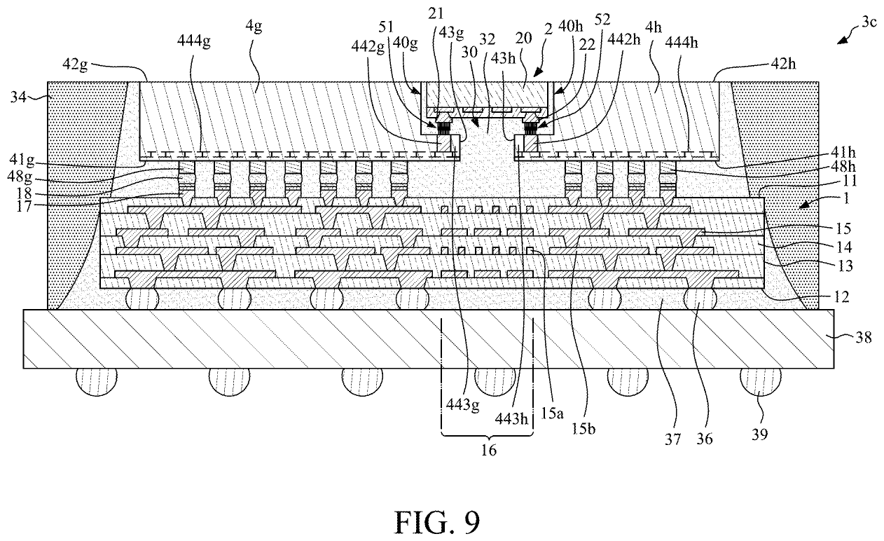

FIG. 9 illustrates a cross-sectional view of a package structure 3c according to some embodiments of the present disclosure. The package structure 3c of FIG. 9 is similar to the package structure 3 of FIG. 1 and the package structure 3′ of FIG. 6, and the differences will be described below.

The first electronic device 4g may be a semiconductor device such as an application specific integrated circuit (ASIC) die or a high bandwidth memory (HBM) die. In some embodiments, the first electronic device 4g may have a first surface 41g (e.g., a bottom surface), a second surface 42g (e.g., a top surface) opposite to the first surface 41g, and a lateral surface 43g extending between the first surface 41g and the second surface 42g. In some embodiments, the first electronic device 4g may further include a first circuit structure 444g and a plurality of first electrical connectors 48g (such as bumps, studs, pillars or posts). The first circuit structure 444g may be disposed adjacent to the first surface 41g of the first electronic device 4g. Thus, the first surface 41g may be a first active surface. The first electrical connectors 48g may be disposed adjacent to the first surface 41g of the first electronic device 4g, and may be electrically connected to the first circuit structure 444g. The first electrical connectors 48g may be electrically connected and physically connected to the protrusion contacts 17 of the wiring structure 1 through the re-flowable materials 18 (e.g., solder materials 18).

The first electronic device 4g may define a first indentation 40g recessed from the second surface 42g and the lateral surface 43g. Thus, the first electronic device 4g may further include a first protrusion 443g. The first electronic device 4g may further include a first via 442g disposed in the first protrusion 443g. An upper portion of the first via 442g may be exposed by a top surface of the first protrusion 443g. A plurality of wires 50 may be disposed on the exposed upper portion of the first via 442g. A lower portion of the first via 442g may be electrically connected to the first circuit structure 444g.

The second electronic device 4h may be a semiconductor device such as an application specific integrated circuit (ASIC) die or a high bandwidth memory (HBM) die. In some embodiments, the second electronic device 4h may have a first surface 41h (e.g., a bottom surface), a second surface 42h (e.g., a top surface) opposite to the first surface 41h, and a lateral surface 43h extending between the first surface 41h and the second surface 42h. In some embodiments, the second electronic device 4h may further include a second circuit structure 444h and a plurality of second electrical connectors 48h (such as bumps, studs, pillars or posts). The second circuit structure 444h may be disposed adjacent to the first surface 41h of the second electronic device 4h. Thus, the first surface 41h may be a second active surface. The second electrical connectors 48h may be disposed adjacent to the first surface 41h of the second electronic device 4h, and may be electrically connected to the second circuit structure 444h. The second electrical connectors 48h may be electrically connected and physically connected to the protrusion contacts 17 of the wiring structure 1 through the re-flowable materials 18 (e.g., solder materials 18).

The second electronic device 4h may define a second indentation 40h recessed from the second surface 42h and the lateral surface 43h. Thus, the second electronic device 4h may further include a second protrusion 443h. The second electronic device 4h may further include a second via 442h disposed in the second protrusion 443h. An upper portion of the second via 442h may be exposed by a top surface of the second protrusion 443h. A plurality of wires 50 may be disposed on the exposed upper portion of the second via 442h. A lower portion of the second via 442h may be electrically connected to the second circuit structure 444h.

The bridge structure 2 may be disposed in the first indentation 40g of the first electronic device 4g and the second indentation 40h of the second electronic device 4h. Thus, the bridge structure 2 may be disposed over the wiring structure 1, and disposed over the first protrusion 443g and the second protrusion 443h. The bridge structure 2 may be electrically connected and physically connected to the exposed upper portion of the first via 442g through the first restriction structure 51. Thus, the bridge structure 2 may be electrically connected to the first active surface 41g of the first electronic device 4g through the first via 442g in the first protrusion 443g of the first electronic device 4g. Similarly, the bridge structure 2 may be electrically connected and physically connected to the exposed upper portion of the second via 442h through the second restriction structure 52. Thus, the bridge structure 2 may be electrically connected to the second active surface 41h of the second electronic device 4h through the second via 442h in the second protrusion 443h of the second electronic device 4h. Therefore, the second electronic device 4h may be electrically connected to the first electronic device 4g through the wires 25 (FIG. 2) of the bridge structure 2. The first restriction structure 51 and the second restriction structure 52 of FIG. 9 may be same as or similar to the first restriction structure 51 and the second restriction structure 52 of FIG. 1.

In addition, the second protection material 34 may further cover and contact the lateral surface 13 of the wiring structure 1, the third protection material 37 (e.g., underfill) and the upper surface of the substrate 38.

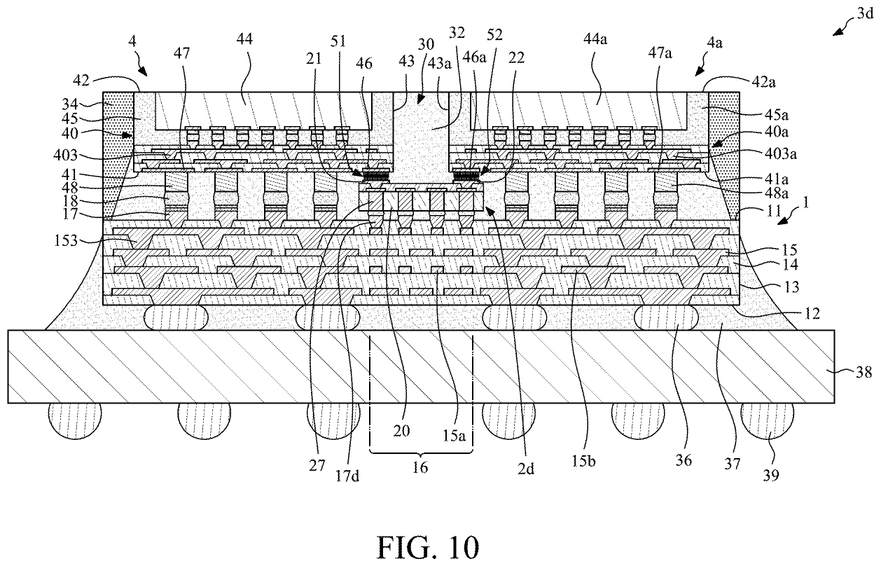

FIG. 10 illustrates a cross-sectional view of a package structure 3d according to some embodiments of the present disclosure. The package structure 3d of FIG. 10 is similar to the package structure 3 of FIG. 1 and the package structure 3′ of FIG. 6, except for a structure of the bridge structure 2d. The bridge structure 2d may include a plurality of conductive vias 27 substantially extending through the main body of the bridge structure 2d. The conductive via 27 may electrically connect a top surface of the bridge structure 2d to a bottom surface of the bridge structure 2d. An upper portion of the conductive via 27 may electrically connect the first contact 21 or the third contact 22 of the interposer 2. A lower portion of the conductive via 27 may electrically connect a protrusion contact 17d of the wiring structure 1 through a re-flowable material 18 (e.g., a solder material 18). Thus, the bridge structure 2d may be electrically connected to the wiring structure 1. The first electronic device 4 and the second electronic device 4a may be electrically connected to the wiring structure 1 through the first restriction structure 51, the second restriction structure 52 and the conductive vias 27 in the bridge structure 2d.

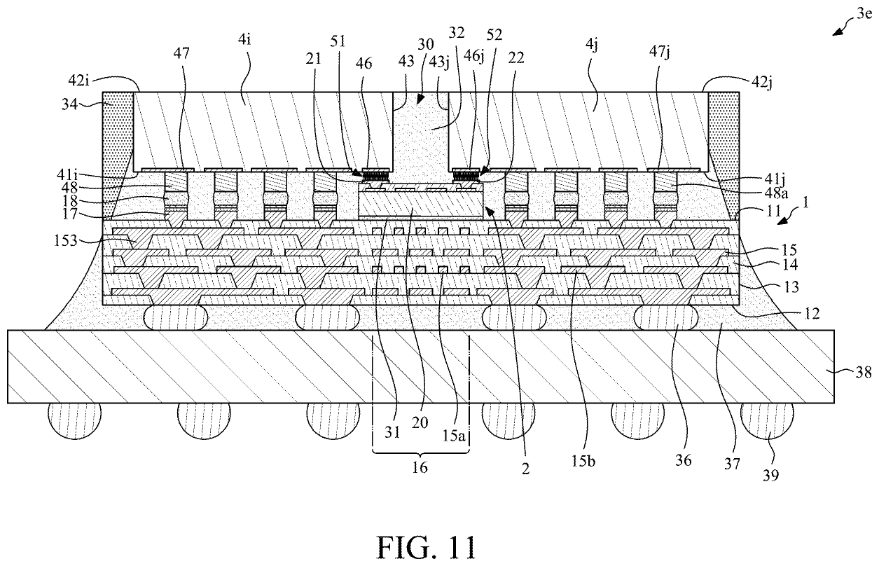

FIG. 11 illustrates a cross-sectional view of a package structure 3e according to some embodiments of the present disclosure. The package structure 3e of FIG. 11 is similar to the package structure 3 of FIG. 1 and the package structure 3′ of FIG. 6, and the differences will be described below.

The first electronic device 4i may be a semiconductor device such as an application specific integrated circuit (ASIC) die or a high bandwidth memory (HBM) die. In some embodiments, the first electronic device 4i may have a first surface 41i (e.g., a bottom surface), a second surface 42i (e.g., a top surface) opposite to the first surface 41i, and a lateral surface 43i extending between the first surface 41ᵢ and the second surface 42i. In some embodiments, the first electronic device 4i may further include a first contact 46 and a plurality of bonding contacts 47 exposed by the first surface 41i. The first contact 46 may be a first pad, and the bonding contact 47 may be a bonding pad. The first electrical connectors 48 may be electrically connected to the bonding contacts 47. The first restriction structure 51 may be electrically connected to the first contact 46.

The second electronic device 4j may be a semiconductor device such as an application specific integrated circuit (ASIC) die or a high bandwidth memory (HBM) die. In some embodiments, the second electronic device 4j may have a first surface 41j (e.g., a bottom surface), a second surface 42j (e.g., a top surface) opposite to the first surface 41j, and a lateral surface 43j extending between the first surface 41j and the second surface 42j. In some embodiments, the second electronic device 4j may further include a second contact 46j and a plurality of bonding contacts 47j exposed by the first surface 41j. The second contact 46j may be a first pad, and the bonding contact 47j may be a bonding pad. The second electrical connectors 48a may be electrically connected to the bonding contacts 47j. The second restriction structure 52 may be electrically connected to the second contact 46j.

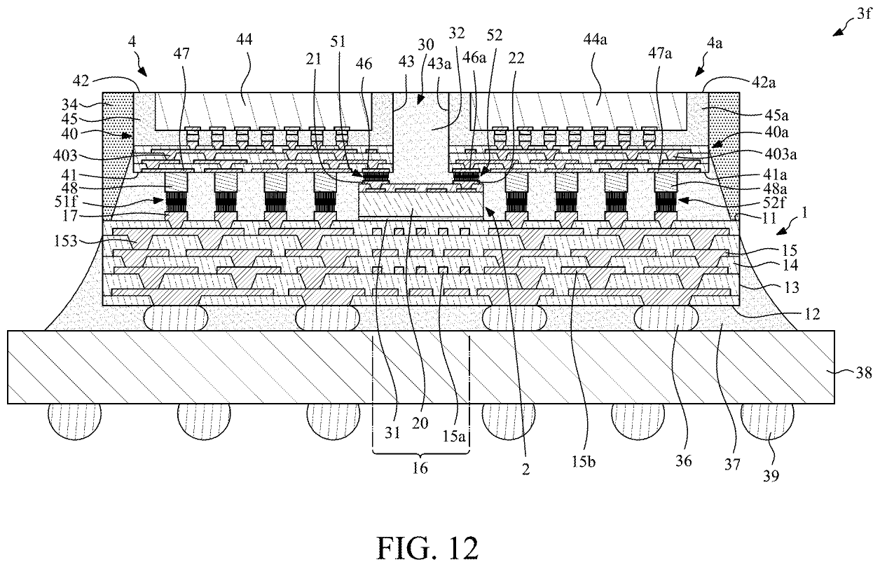

FIG. 12 illustrates a cross-sectional view of a package structure 3f according to some embodiments of the present disclosure. The package structure 3f of FIG. 12 is similar to the package structure 3 of FIG. 1 and the package structure 3′ of FIG. 6, except that the re-flowable material 18 (e.g., solder material 18) are replaced by the restriction structures 51f, 52f. The restriction structure 51f may be same as or similar to the first restriction structure 51, and may be configured to connect the first electrical connector 48 and the protrusion contact 17 of the wiring structure 1. The restriction structure 52f may be same as or similar to the second restriction structure 52, and may be configured to connect the second electrical connector 48a and the protrusion contact 17 of the wiring structure 1.

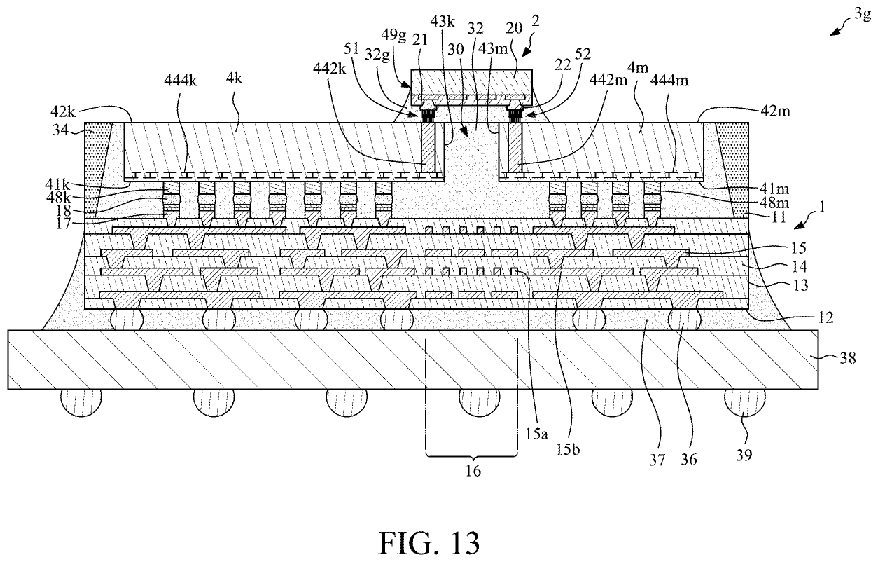

FIG. 13 illustrates a cross-sectional view of a package structure 3g according to some embodiments of the present disclosure. The package structure 3g of FIG. 13 is similar to the package structure 3c of FIG. 9, and the differences will be described below.

The first electronic device 4k may have a first surface 41k (e.g., a bottom surface), a second surface 42k (e.g., a top surface) opposite to the first surface 41k, and a lateral surface 43k extending between the first surface 41k and the second surface 42k. In some embodiments, the first electronic device 4k may further include a first circuit structure 444k and a plurality of first electrical connectors 48k (such as bumps, studs, pillars or posts). The first circuit structure 444k may be disposed adjacent to the first surface 41k of the first electronic device 4k. Thus, the first surface 41k may be a first active surface. The first electrical connectors 48k may be disposed adjacent to the first surface 41k of the first electronic device 4k, and may be electrically connected to the first circuit structure 444k. The first electrical connectors 48k may be electrically connected and physically connected to the protrusion contacts 17 of the wiring structure 1 through the re-flowable materials 18 (e.g., solder materials 18).

The first electronic device 4k may include a first via 442k. An upper portion of the first via 442k may be exposed by the second surface 42k of the first electronic device 4k. A plurality of wires 50 may be disposed on the exposed upper portion of the first via 442k. A lower portion of the first via 442k may be electrically connected to the first circuit structure 444k.

The second electronic device 4m may have a first surface 41m (e.g., a bottom surface), a second surface 42m (e.g., a top surface) opposite to the first surface 41m, and a lateral surface 43m extending between the first surface 41m and the second surface 42m. In some embodiments, the second electronic device 4m may further include a second circuit structure 444m and a plurality of second electrical connectors 48m (such as bumps, studs, pillars or posts). The second circuit structure 444m may be disposed adjacent to the first surface 41m of the second electronic device 4m. Thus, the first surface 41m may be a second active surface. The second electrical connectors 48m may be disposed adjacent to the first surface 41m of the second electronic device 4m, and may be electrically connected to the second circuit structure 444m. The second electrical connectors 48m may be electrically connected and physically connected to the protrusion contacts 17 of the wiring structure 1 through the re-flowable materials 18 (e.g., solder materials 18).

The second electronic device 4m may include a second via 442m. An upper portion of the second via 442m may be exposed by the second surface 42m of the second electronic device 4m. A plurality of wires 50 may be disposed on the exposed upper portion of the second via 442m. A lower portion of the second via 442m may be electrically connected to the second circuit structure 444m.

The bridge structure 2 may be disposed on the second surface 42k of the first electronic device 4k and the second surface 42m of the second electronic device 4m. Thus, the bridge structure 2 may be disposed over the first electronic device 4k and the second electronic device 4m. The bridge structure 2 may be electrically connected and physically connected to the exposed upper portion of the first via 442k through the first restriction structure 51. Thus, the bridge structure 2 may be electrically connected to the first active surface 41k of the first electronic device 4k through the first via 442k. Similarly, the bridge structure 2 may be electrically connected and physically connected to the exposed upper portion of the second via 442m through the second restriction structure 52. Thus, the bridge structure 2 may be electrically connected to the second active surface 41m of the second electronic device 4m through the second via 442m. Therefore, the second electronic device 4m may be electrically connected to the first electronic device 4k through the wires 25 (FIG. 2) of the bridge structure 2. The first restriction structure 51 and the second restriction structure 52 of FIG. 13 may be same as or similar to the first restriction structure 51 and the second restriction structure 52 of FIG. 1 and FIG. 6.

In addition, a protection material 32g may further cover and contact the first restriction structure 51, the second restriction structure 52, the second surface 42k of the first electronic device 4k, the second surface 42m of the second electronic device 4m and the first protection material 32.

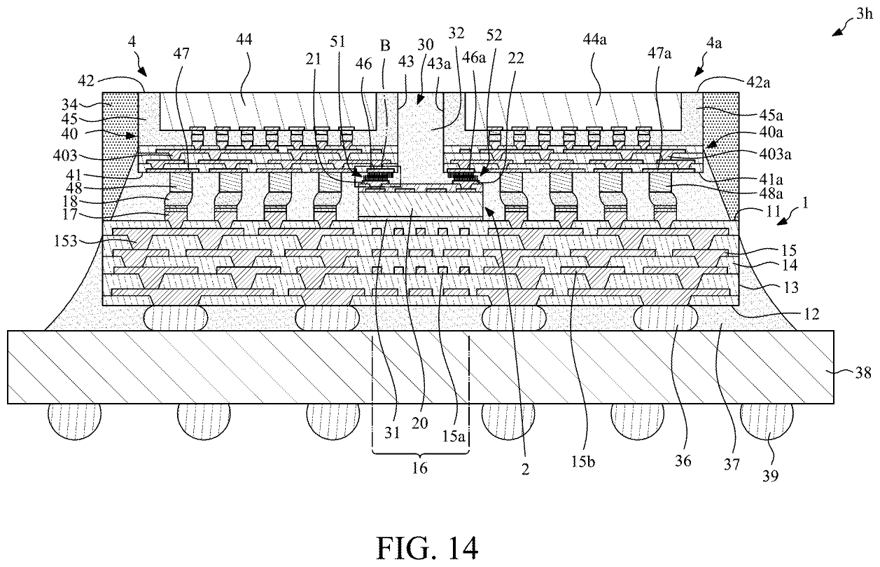

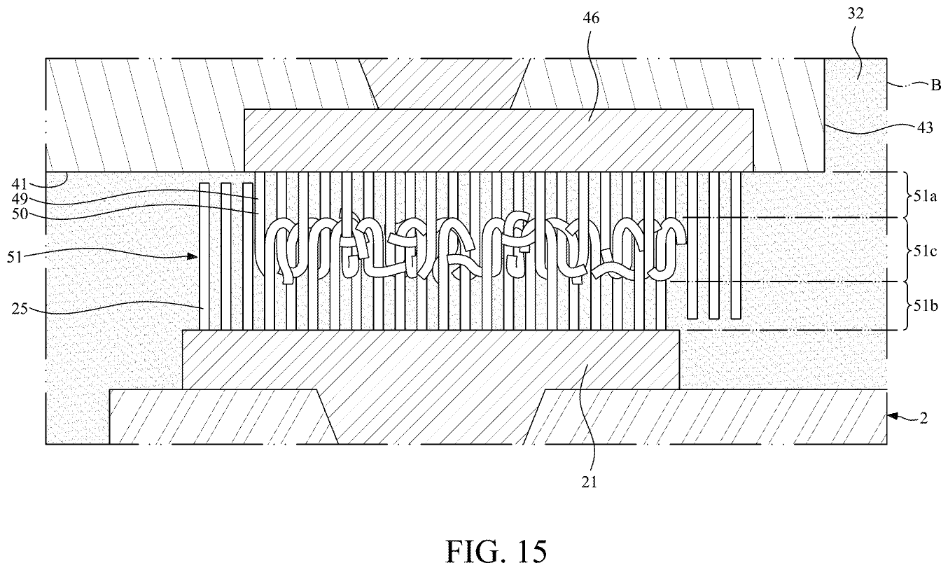

FIG. 14 illustrates a cross-sectional view of a package structure 3h according to some embodiments of the present disclosure. FIG. 15 illustrates a partially enlarged view of a region “B” in FIG. 14. The package structure 3h of FIG. 14 is similar to the package structure 3 of FIG. 1 and the package structure 3′ of FIG. 6, except that the first electronic device 4 and the second electronic device 4a may be shifted. Thus, the first electrical connectors 48 and the second electrical connectors 48a may be misaligned with the protrusion contacts 17 of the wiring structure 1. The first electrical connector 48 may be a soldering structure electrically connected to the first electronic device 4. An upper portion of the first electrical connector 48 (e.g., the soldering structure) may be misaligned with a lower portion of the first electrical connector 48. As shown in FIG. 15, some of the first lower wires 25 may not contact the first upper wires 49, and some of the first upper wires 49 may not contact the first lower wires 25.

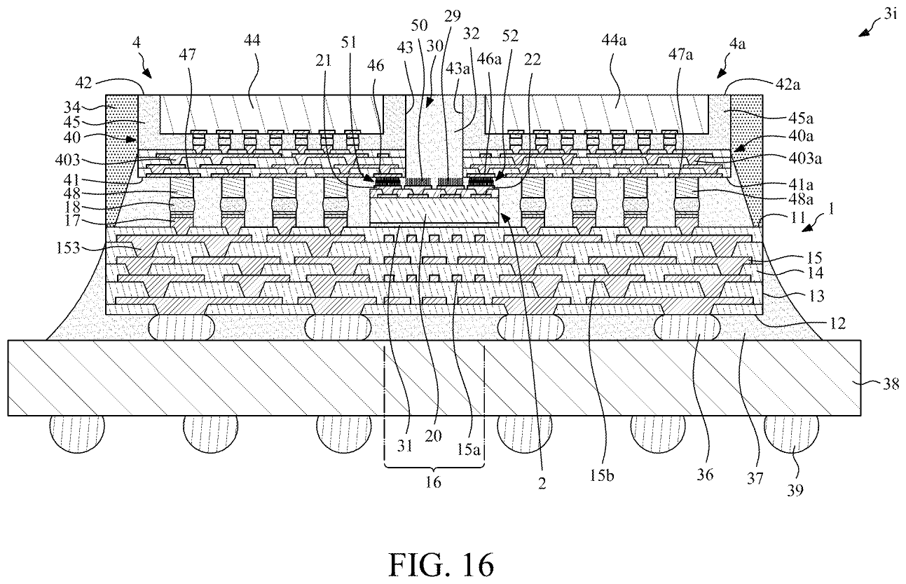

FIG. 16 illustrates a cross-sectional view of a package structure 3i according to some embodiments of the present disclosure. The package structure 3i of FIG. 16 is similar to the package structure 3 of FIG. 1 and the package structure 3′ of FIG. 6, and the differences will be described below. The bridge interposer 2 may further includes a plurality of third wires 29 disposed under the gap 30 between the first electronic device 4 and the second electronic device 4a. The third wires 29 may be dummy, and may have no electrical function. Thus, the third wires 29 may not electrically connect the first electronic device 4 and the second electronic device 4a. In addition, the first protection material 32 (e.g., the underfill) may extend into a gap or a space between the third wires 29 so as to increase an adhesion between the first protection material 32 and the third wires 29. The third wires 29 may facilitate holding the first protection material 32, and may reduce a risk of delamination of the first protection material 32.

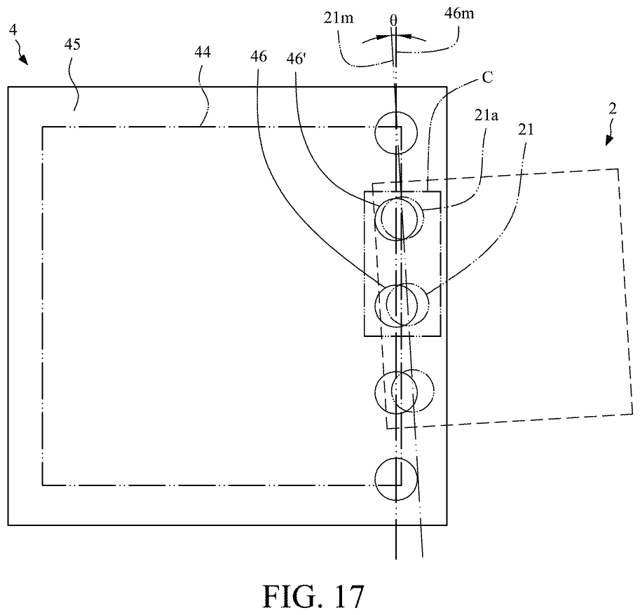

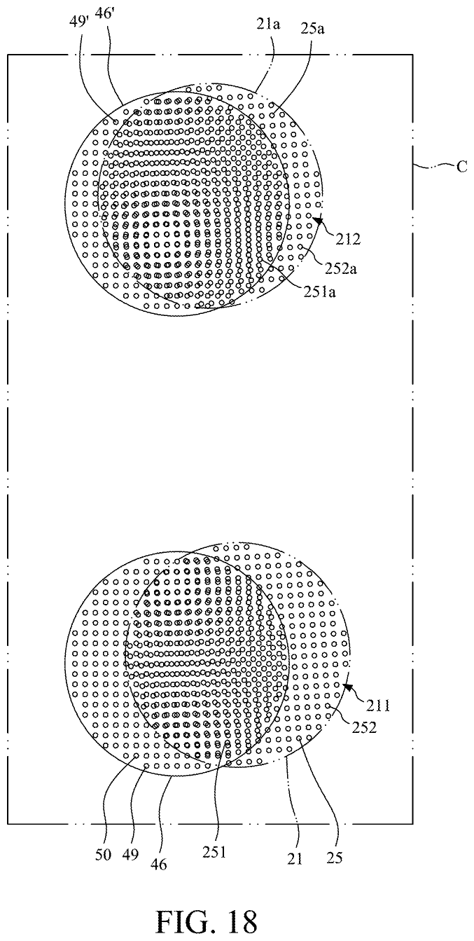

FIG. 17 illustrates a top view of a relative position between the first electronic device 4 and the interposer 2. FIG. 18 illustrates a partially enlarged view of a region “C” in FIG. 17. The interposer 2 may be shifted with respect to the first electronic device 4. A lateral surface of the interposer 2 may be non-parallel with a lateral surface of the first electronic device 4. The first electronic device 4 may include the first contact 46 and a second contact 46′. The wires (e.g., the first wires 49) of the first electronic device 4 may be disposed on the first contact 46 and the second contact 46′. The interposer 2 (or the reinforcement structure 2) may include the first contact 21 and a second contact 21a. The first lower wires 25, 26 of the reinforcement structure 2 (or the bridge interposer 2) may be disposed on the first contact 21 and a second contact 21a. An imaginary line 21m passing through the centers of the first contact 21 and the second contact 21a of the interposer 2 (or the reinforcement structure 2) may be non-parallel with an imaginary line 46m passing through the centers of the first contact 46 and the second contact 46′ of the first electronic device 4 from a top view. An intersection angle 0 between the imaginary line 21m and the imaginary line 46m may be greater than 0 degree, less than 1 degree, less than 3 degrees, less than 5 degrees, less than 10 degrees, or less than 15 degrees.

The wires 50 may include the first lower wires 25 (or the second wires 25) and the first upper wires 49 (or the first wires 49). The first lower wires 25 may be disposed on the first contact 21 of the interposer 2. The first upper wires 49 may be disposed on the first contact 46 of the first electronic device 4. The first contact 21 of the interposer 2 may be misaligned with the first contact 46 of the first electronic device 4. A first group 251 of the first lower wires 25 (or the second wires 25) contacts the first upper wires 49 (or the first wires 49). A second group 252 of the first lower wires 25 (or the second wires 25) is free from contacting the first upper wires 49 (or the first wires 49). The second group 252 of the first lower wires 25 (or the second wires 25) is spaced apart from the first upper wires 49 (or the first wires 49). The second group 252 of the first lower wires 25 may be disposed outside a vertical projection of the first contact 46 of the first electronic device 4. The second group 252 of the first lower wires 25 may occupy an area 211.

The wires 50 may further include a plurality of second lower wires 25a (or the sixth wires 25a) and a plurality of second upper wires 49′ (or the fifth wires 49′). The second lower wires 25a may be disposed on the second contact 21a of the interposer 2. The second upper wires 49′ may be disposed on the second contact 46′ of the first electronic device 4. The second contact 21a of the interposer 2 may be misaligned with the second contact 46′ of the first electronic device 4. A first group 251a of the second lower wires 25a (or the sixth wires 25a) contacts the second upper wires 49′ (or the fifth wires 49′). A second group 252a of the second lower wires 25a (or the sixth wires 25a) is free from contacting the second upper wires 49′ (or the fifth wires 49′). The second group 252a of the second lower wires 25a (or the sixth wires 25a) is spaced apart from the second upper wires 49′ (or the fifth wires 49′). The second group 252a of the second lower wires 25a may be disposed outside a vertical projection of the second contact 46′ of the first electronic device 4. The second group 252a of the second lower wires 25a may occupy an area 212. A size and a shape of the area 212 may be different from a size and a shape of the area 211. The area 212 may be larger than or smaller than the area 211.

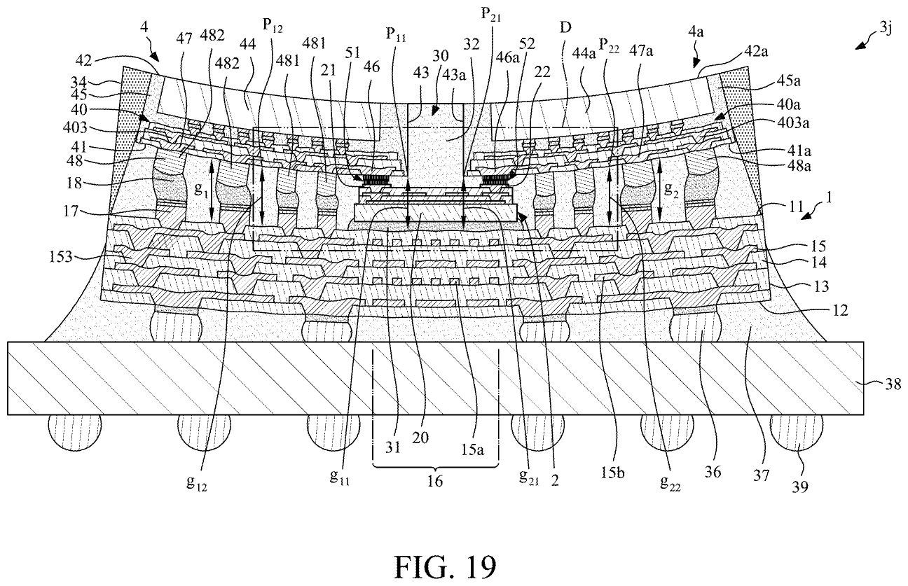

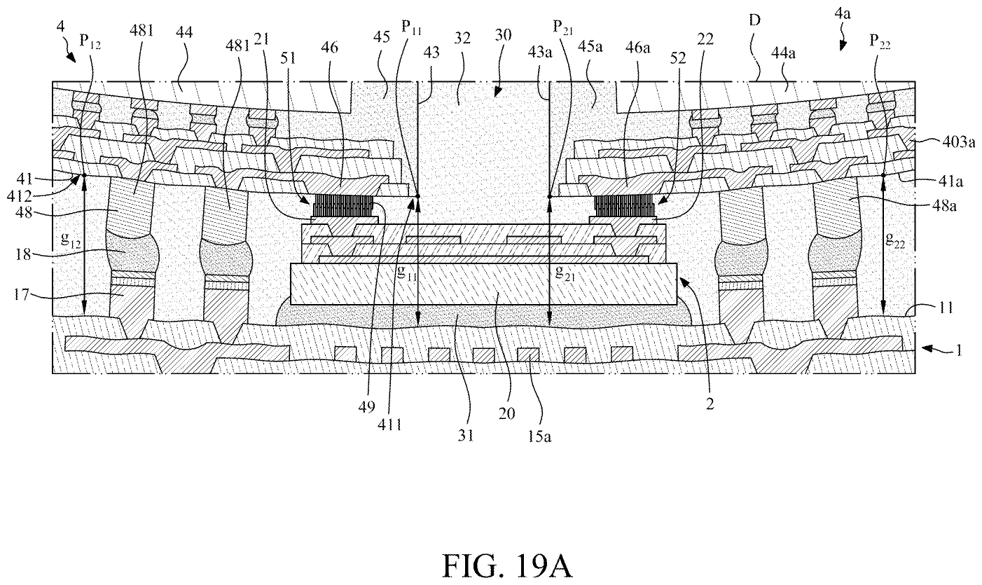

FIG. 19 illustrates a cross-sectional view of a package structure 3j according to some embodiments of the present disclosure. FIG. 19A illustrates a partially enlarged view of a region “D” in FIG. 19. The package structure 3j of FIG. 19 is similar to the package structure 3 of FIG. 1 and the package structure 3′ of FIG. 6, except for the occurrence of warpage.

The wiring structure 1 may have a concave warpage. The first electronic device 4 may have a concave warpage. A curvature of the first electronic device 4 may be greater than a curvature of the wiring structure 1. A radius of the curvature of the first electronic device 4 may be less than the radius of the curvature of the wiring structure 1. A gap g₁ between the first electronic device 4 and the wiring structure 1 may increase gradually toward the lateral surface 13 of the wiring structure 1. The gap g₁ between the first electronic device 4 and the wiring structure 1 may decrease gradually toward the interposer 2 (or bridge structure 2), the first restriction structure 51 or the gap 30. For example, the first electronic device 4 may have a first point P₁₁ and a second point P₁₂. The first point P₁₁ may be disposed between the first restriction structure 51 and the gap 30. The first point P₁₁ may be disposed at a corner of the first electronic device 4. The first point P₁₁ may be closer to the gap 30 than the second point P₁₂ is. The first point P₁ may be closer to a center of the interposer 2 than the second point P₁₂ is. A gap g₁₁ between the first electronic device 4 and the wiring structure 1 at the first point P₁₁ may be less than a gap g₁₂ between the first electronic device 4 and the wiring structure 1 at the second point P₁₂. For example, the first electronic device 4 may include a first area 411 and a second area 412. The first point P₁₁ may be disposed in the first area 411. The second point P₁₂ may be disposed in the second area 412. The first area 411 may be closer to the first wires 49 than the second area 412 is. The gap g₁₁ between the first area 411 and the top surface 11 of the wiring structure 1 is less than the gap g₁₂ between the second area 412 and the top surface 11 of the wiring structure 1.

Similarly, the second electronic device 4a may have a concave warpage. A curvature of the second electronic device 4a may be greater than the curvature of the wiring structure 1. A radius of the curvature of the second electronic device 4a may be less than the curvature of the radius of the curvature of the wiring structure 1. A gap g₂ between the second electronic device 4a and the wiring structure 1 may increase gradually toward another lateral surface 13 of the wiring structure 1. The gap g₂ between the second electronic device 4a and the wiring structure 1 may decrease gradually toward the interposer 2, the second restriction structure 52 or the gap 30. For example, the second electronic device 4a may have a first point P₂₁ and a second point P₂₂. The first point P₂₁ may be disposed between the second restriction structure 52 and the gap 30. The first point P₂₁ may be disposed at a corner of the second electronic device 4a. The first point P₂₁ may be closer to the gap 30 than the second point P₂₂ is. The first point P₂₁ may be closer to a center of the interposer 2 than the second point P₂₂ is. A gap g₂₁ between the second electronic device 4a and the wiring structure 1 at the first point P₂₁ may be less than a gap g₂₂ between the second electronic device 4a and the wiring structure 1 at the second point P₂₂.

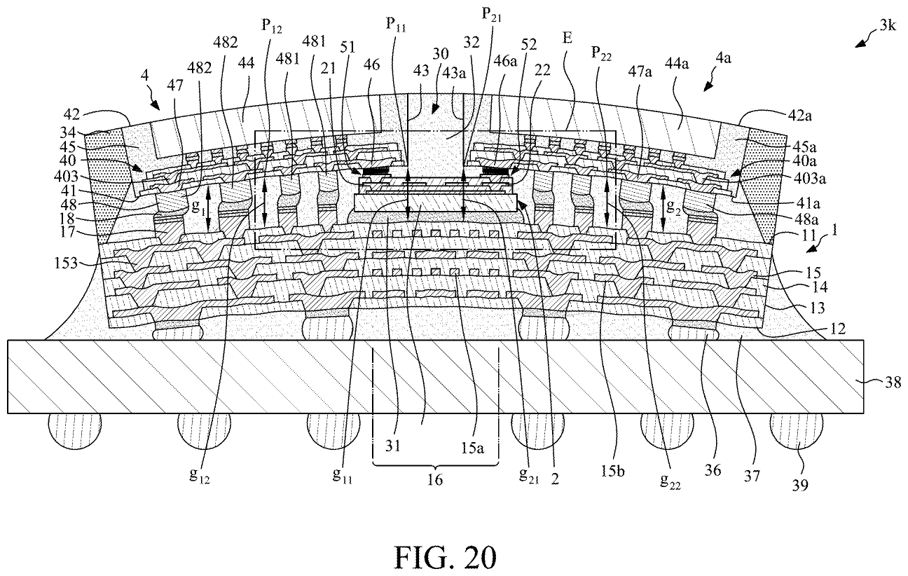

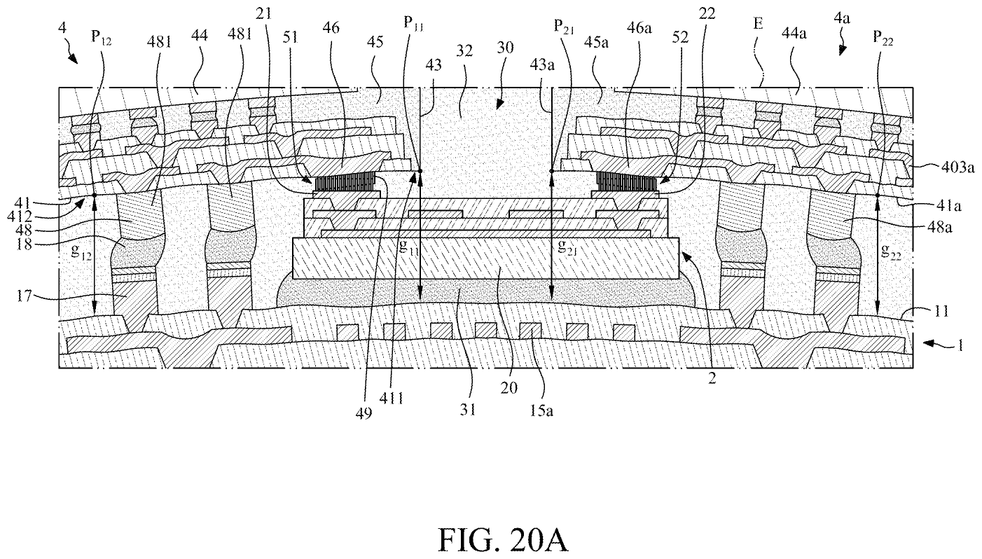

FIG. 20 illustrates a cross-sectional view of a package structure 3k according to some embodiments of the present disclosure. FIG. 20A illustrates a partially enlarged view of a region “E” in FIG. 20. The package structure 3k of FIG. 20 is similar to the package structure 3 of FIG. 1 and the package structure 3′ of FIG. 6, except for the occurrence of warpage.

The wiring structure 1 may have a convex warpage. The first electronic device 4 may have a convex warpage. A curvature of the first electronic device 4 may be greater than a curvature of the wiring structure 1. A radius of the curvature of the first electronic device 4 may be less than the radius of the curvature of the wiring structure 1. A gap g1 between the first electronic device 4 and the wiring structure 1 may increase gradually toward the interposer 2, the first restriction structure 51 or the gap 30. The gap g1 between the first electronic device 4 and the wiring structure 1 may decrease gradually toward the lateral surface 13 of the wiring structure 1. For example, the first electronic device 4 may have a first point P₁₁ and a second point P₁₂. The first point P₁₁ may be disposed between the first restriction structure 51 and the gap 30. The first point P₁₁ may be closer to the gap 30 than the second point P₁₂ is. The first point P₁₁ may be closer to a center of the interposer 2 than the second point P₁₂ is. A gap g₁₁ between the first electronic device 4 and the wiring structure 1 at the first point P₁₁ may be greater than a gap g₁₂ between the first electronic device 4 and the wiring structure 1 at the second point P₁₂. For example, the first electronic device 4 may include a first area 411 and a second area 412. The first point P₁₁ may be disposed in the first area 411. The second point P₁₂ may be disposed in the second area 412. The first area 411 may be closer to the first wires 49 than the second area 412 is. The gap g₁₁ between the first area 411 and the top surface 11 of the wiring structure 1 is greater than the gap g₁₂ between the second area 412 and the top surface 11 of the wiring structure 1.

Similarly, the second electronic device 4a may have a convex warpage. A curvature of the second electronic device 4a may be greater than the curvature of the wiring structure 1. A radius of the curvature of the second electronic device 4a may be less than the curvature of the radius of the curvature of the wiring structure 1. A gap g₂ between the second electronic device 4a and the wiring structure 1 may increase gradually toward the interposer 2, the second restriction structure 52 or the gap 30. The gap g₂ between the second electronic device 4a and the wiring structure 1 may decrease gradually toward the lateral surface 13 of the wiring structure 1. For example, the second electronic device 4a may have a first point P₂₁ and a second point P₂₂. The first point P₂₁ may be disposed between the second restriction structure 52 and the gap 30. The first point P₂₁ may be closer to the gap 30 than the second point P₂₂ is. The first point P₂₁ may be closer to a center of the interposer 2 than the second point P₂₂ is. A gap g₂₁ between the second electronic device 4a and the wiring structure 1 at the first point P₂₁ may be greater than a gap g₂₂ between the second electronic device 4a and the wiring structure 1 at the second point P₂₂.

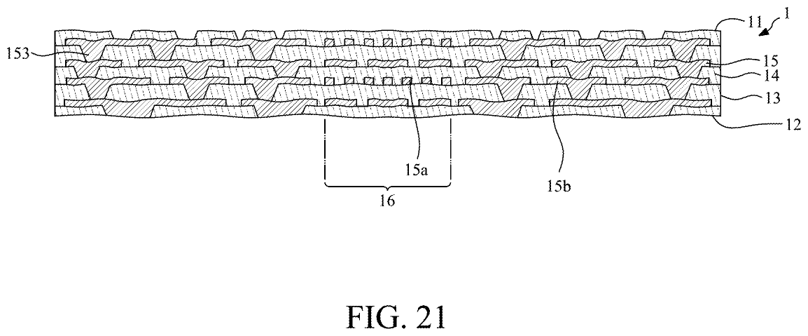

FIG. 21 through FIG. 26 illustrate a method for manufacturing a package structure according to some embodiments of the present disclosure. In some embodiments, the method is for manufacturing the package structure 3 shown in FIG. 1.

Referring to FIG. 21, a wiring structure 1 may be provided. The wiring structure 1 of FIG. 21 may be same as or similar to the wiring structure 1 of FIG. 1.

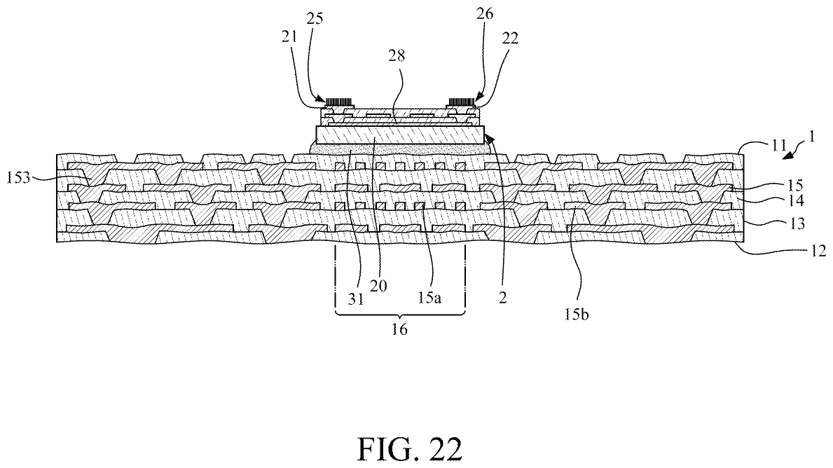

Referring to FIG. 22, an interposer 2 may be attached to the first surface 11 of the wiring structure 1 through the adhesion layer 31. The interposer 2 of FIG. 22 may be same as or similar to the interposer 2 of FIG. 1. The interposer 2 may include a plurality of first lower wires 25 disposed on the first contact 21 and the third contact 22 of the interposer 2.

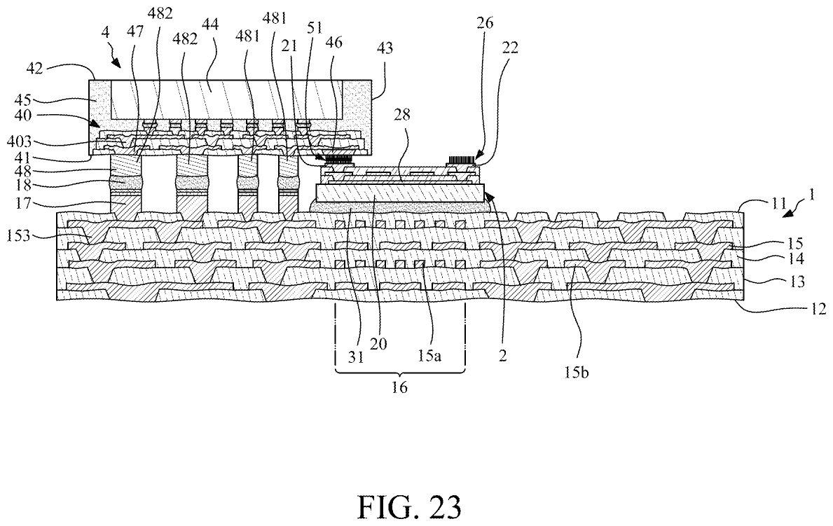

Referring to FIG. 23, a first electronic device 4 may be attached to the wiring structure 1 and the interposer 2. The first electronic device 4 of FIG. 23 may be same as or similar to the first electronic device 4 of FIG. 1. In some embodiments, the first electrical connectors 48 of the first electronic device 4 may be electrically connected and physically connected to the protrusion contacts 17 of the wiring structure 1 through a plurality of re-flowable materials 18 (e.g., solder materials 18). The first upper wires 49 on the first contact 46 of the first electronic device 4 may contact the first lower wires 25 on the first contact 21 of the interposer 2, or the first upper wires 49 may insert into the spacing between the first lower wires 25 so as to form a first restriction structure 51.

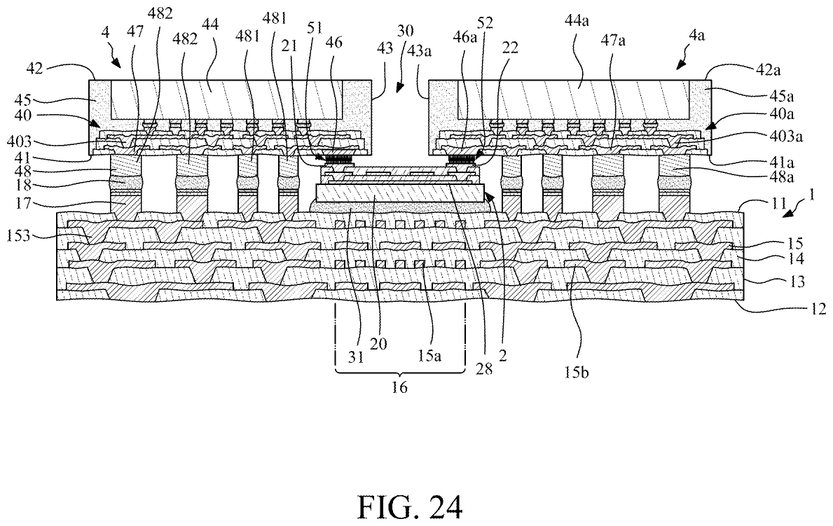

Referring to FIG. 24, a second electronic device 4a may be attached to the wiring structure 1 and the interposer 2. The second electronic device 4a of FIG. 24 may be same as or similar to the second electronic device 4a of FIG. 1. In some embodiments, the second electrical connectors 48a of the second electronic device 4a may be electrically connected and physically connected to the protrusion contacts 17 of the wiring structure 1 through a plurality of re-flowable materials 18 (e.g., solder materials 18). The first upper wires 49 on the first contact 46a of the second electronic device 4a may contact the first lower wires 25 on the third contact 22 of the interposer 2, or the first upper wires 49 may insert into the spacing between the first lower wires 25 so as to form a second restriction structure 52.

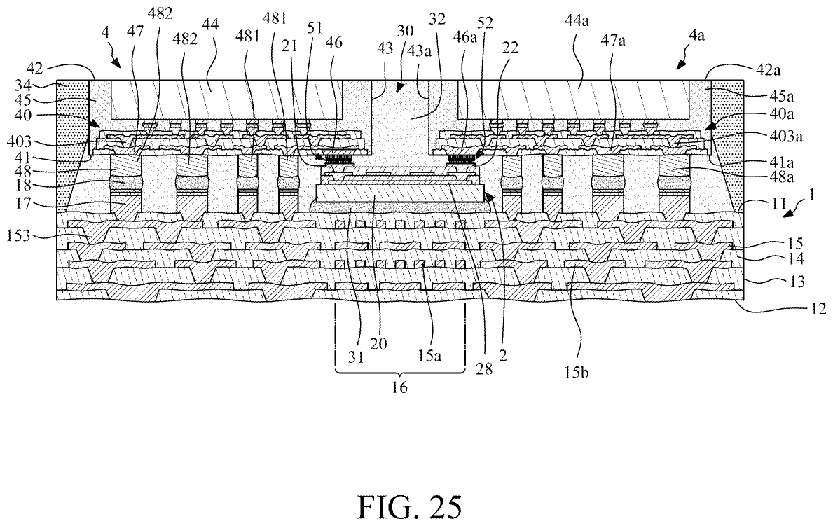

Referring to FIG. 25, a first protection material 32 (i.e., an underfill) may be formed or disposed in a first space between the first electronic device 4 and the wiring structure 1 and a second space between the second electronic device 4a and the wiring structure 1 so as to cover and protect the joints formed by the first electrical connectors 48, the protrusion contacts 17 and the re-flowable materials 18, and the joints formed by the second electrical connectors 48a, the protrusion contacts 17 and the re-flowable materials 18. In addition, the first protection material 32 may cover the interposer 2, and may further extend into the gap 30 between the lateral surface 43 of the first electronic device 4 and the lateral surface 43a of the second electronic device 4a. The first protection material 32 may encapsulate the interposer 2, the first electronic device 4 and the second electronic device 4a.

Then, a second protection material 34 may be formed or disposed to cover at least a portion of the first surface 11 of the wiring structure 1, at least a portion of the first electronic device 4 and at least a portion of the second electronic device 4a. The second protection material 34 may encapsulate the interposer 2, the first electronic device 4, the second electronic device 4a and the first protection material 32. A top surface of the second protection material 34, a second surface 42 of the first electronic device 4, a second surface 42a of the second electronic device 4a and a top surface of the first protection material 32 in the gap 30 may be substantially coplanar with each other.

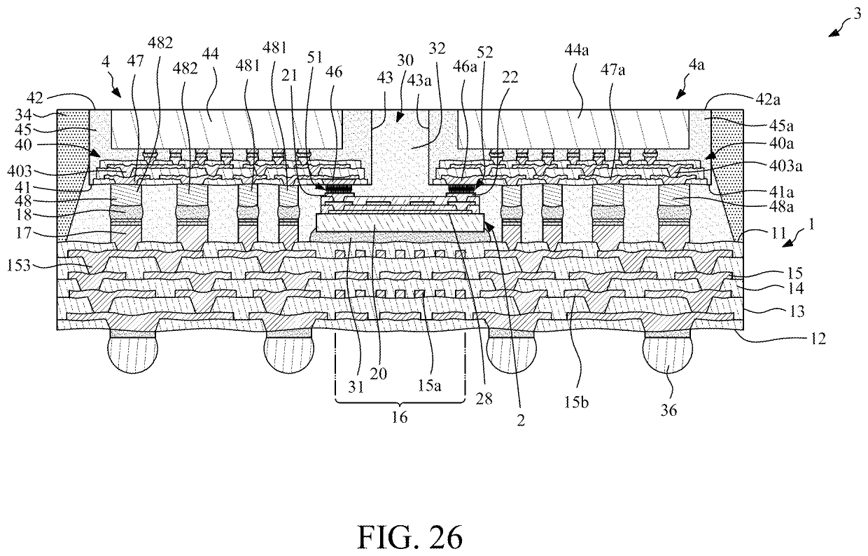

Referring to FIG. 26, a plurality of solder materials 36 (e.g., solder balls) may be formed or disposed on the bottom bumps protruding from the second surface 12 of the wiring structure 1 for external connection. In some embodiments, a singulation process may be conducted to the wiring structure 1 so as to obtain a plurality of package structures 3 shown in FIG. 26 and FIG. 1.

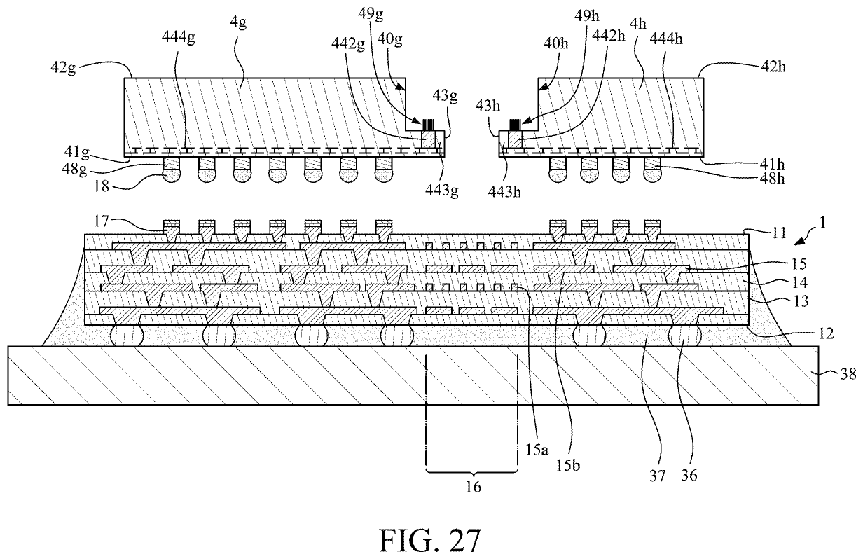

FIG. 27 through FIG. 30 illustrate a method for manufacturing a package structure according to some embodiments of the present disclosure. In some embodiments, the method is for manufacturing the package structure 3c shown in FIG. 9.

Referring to FIG. 27, a wiring structure 1 may be provided on or attached to a substrate 38 through the solder materials 36. The wiring structure 1 and the substrate 38 of FIG. 27 may be same as or similar to the wiring structure 1 and the substrate 38 of FIG. 9, respectively.

A first electronic device 4g and a second electronic device 4h may be provided. The first electronic device 4g and the second electronic device 4h may be same as or similar to the first electronic device 4g and the second electronic device 4h of FIG. 9, respectively. The first electronic device 4g may define a first indentation 40g recessed from the second surface 42g and the lateral surface 43g. Thus, the first electronic device 4g may further include a first protrusion 443g. The first electronic device 4g may further include a first via 442g disposed in the first protrusion 443g. An upper portion of the first via 442g may be exposed by a top surface of the first protrusion 443g. A plurality of first upper wires 49g may be disposed on the exposed upper portion of the first via 442g. In some embodiments, the first electrical connectors 48g of the first electronic device 4g may be electrically connected and physically connected to the protrusion contacts 17 of the wiring structure 1 through a plurality of re-flowable materials 18.

The second electronic device 4h may define a second indentation 40h recessed from the second surface 42h and the lateral surface 43h. Thus, the second electronic device 4h may further include a second protrusion 443h. The second electronic device 4h may further include a second via 442h disposed in the second protrusion 443h. An upper portion of the second via 442h may be exposed by a top surface of the second protrusion 443h. A plurality of first upper wires 49h may be disposed on the exposed upper portion of the second via 442h.

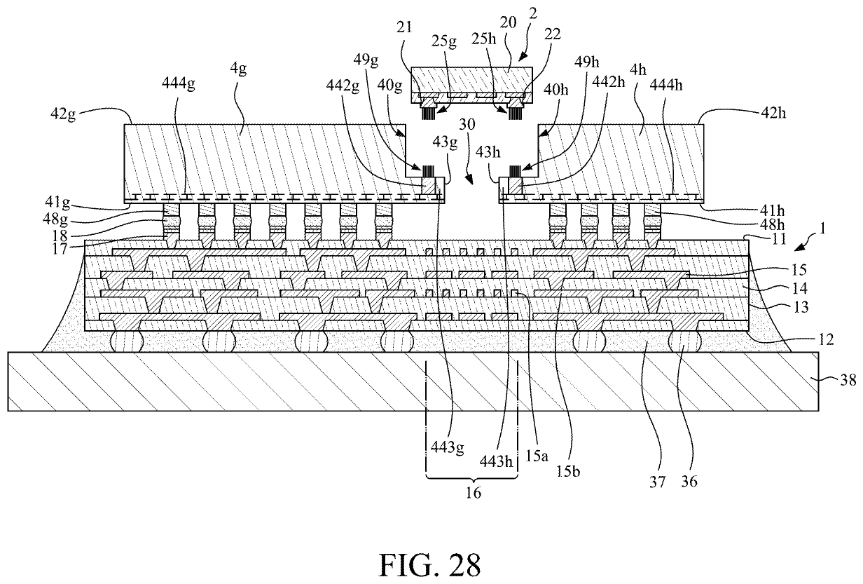

Referring to FIG. 28, a bridge structure 2 may be provided. The bridge structure 2 of FIG. 28 may be same as or similar to the bridge structure 2 of FIG. 9. The bridge structure 2 may include a plurality of first lower wires 25g disposed on the first contact 21 and a plurality of first lower wires 25h disposed on the third contact 22 of the bridge structure 2. Then, the bridge structure 2 may be disposed in the first indentation 40g of the first electronic device 4g and the second indentation 40h of the second electronic device 4h.

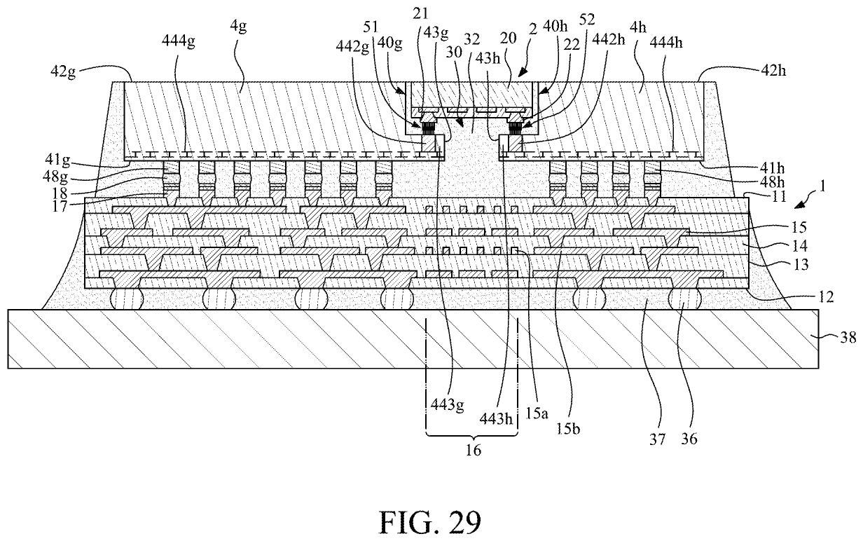

Referring to FIG. 29, the bridge structure 2 may be electrically connected and physically connected to the first electronic device 4g and the second electronic device 4h. In some embodiments, the first lower wires 25g of the bridge structure 2 and the first upper wires 49g of the first electronic device 4g may collectively form a first restriction structure 51. Thus, the bridge structure 2 may be electrically connected and physically connected to the exposed upper portion of the first via 442g through the first restriction structure 51. Similarly, the first lower wires 25h of the bridge structure 2 and the first upper wires 49h of the second electronic device 4h may collectively form a second restriction structure 52. Thus, the bridge structure 2 may be electrically connected and physically connected to the exposed upper portion of the second via 442h through the second restriction structure 52. The first restriction structure 51 and the second restriction structure 52 of FIG. 29 may be same as or similar to the first restriction structure 51 and the second restriction structure 52 of FIG. 9.

Then, a first protection material 32 (i.e., an underfill) may be formed or disposed in a first space between the first electronic device 4g and the wiring structure 1 and a second space between the second electronic device 4h and the wiring structure 1 so as to cover and protect the joints formed by the first electrical connectors 48g, the protrusion contacts 17 and the re-flowable materials 18, and the joints formed by the second electrical connectors 48h, the protrusion contacts 17 and the re-flowable materials 18. In addition, the first protection material 32 may cover the interposer 2, and may further extend into the gap 30 between the lateral surface 43g of the first electronic device 4g and the lateral surface 43h of the second electronic device 4h, the first indentation 40g of the first electronic device 4g and the second indentation 40h of the second electronic device 4h.

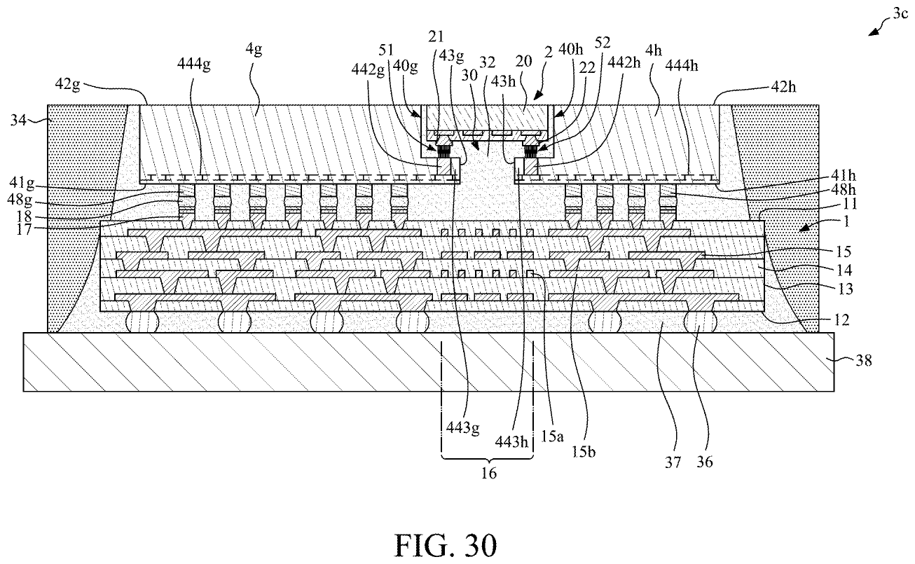

Referring to FIG. 30, a second protection material 34 may be formed or disposed to cover and contact the first protection material 32, the lateral surface 13 of the wiring structure 1, the third protection material 37 and the upper surface of the substrate 38 so as to obtain a package structures 3c on the substrate 38, as shown in FIG. 9.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to +0.5°, less than or equal to ±0.1°, or less than or equal to ±0.05°. For example, a characteristic or quantity can be deemed to be “substantially” consistent if a maximum numerical value of the characteristic or quantity is within a range of variation of less than or equal to +10% of a minimum numerical value of the characteristic or quantity, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a wiring structure having a top surface;
a first electronic device disposed over the top surface of the wiring structure, having a bottom surface facing the top surface of the wiring structure, and including a plurality of first wires; and
a reinforcement structure disposed over the top surface of the wiring structure, and including a plurality of second wires directly contacting the plurality of first wires to reduce a variation of an elevation of the bottom surface of the first electronic device with respect to the top surface of the wiring structure.

2. The package structure of claim 1, further comprising a second electronic device disposed over the top surface of the wiring structure, wherein the second electronic device and the first electronic device are disposed side by side, the second electronic device has a bottom surface facing the top surface of the wiring structure and includes a plurality of third wires, and the reinforcement structure further includes a plurality of fourth wires directly contacting the plurality of third wires to reduce a variation of an elevation of the bottom surface of the second electronic device with respect to the top surface of the wiring structure.

3. The package structure of claim 2, wherein the reinforcement structure further includes a bridge interconnector configured to bridge communication between the first electronic device and the second electronic device.

4. The package structure of claim 1, wherein a group of the plurality of second wires is spaced apart from the plurality of first wires.

5. The package structure of claim 4, wherein the first electronic device further includes a plurality of fifth wires, the reinforcement structure further includes a plurality of sixth wires, wherein a first group of the plurality of sixth wires contacts the plurality of fifth wires, and a second group of the plurality of sixth wires is free from contacting the plurality of fifth wires, wherein an area occupied by the second group of the plurality of sixth wires is different from an area occupied by the group of the plurality of second wires.

6. The package structure of claim 4, wherein the reinforcement structure includes a first contact and a second contact, the first electronic device includes a first contact and a second contact, wherein the second wires are disposed on the first contact and the second contact of the reinforcement structure, the first wires are disposed on the first contact and the second contact of the first electronic device, wherein an imaginary line passing through the centers of the first contact and the second contact of the reinforcement structure is non-parallel with an imaginary line passing through the centers of the first contact and the second contact of the first electronic device from a top view.

7. The package structure of claim 1, wherein the first electronic device has a lower surface facing the top surface of the wiring structure and including a first area and a second area, the first area is closer to the plurality of first wires than the second area is, and a gap between the first area and the top surface of the wiring structure is less than a gap between the second area and the top surface of the wiring structure.

8. The package structure of claim 1, further comprising a re-flowable material electrically connected to the first electronic device and the wiring structure.

9. A package structure, comprising:
a bridge interposer;
a first electronic device disposed over the bridge interposer; and
a second electronic device disposed over the bridge interposer, and is communicated with the first electronic device through the bridge interposer;
wherein the bridge interposer includes a first pad, a second pad, a plurality of first wires disposed on the first pad and a plurality of second wires disposed on the second pad, the first pad is electrically connected to the first electronic device through the plurality of first wires, and the second pad is electrically connected to the second electronic device through the plurality of second wires.

10. The package structure of claim 9, further comprising an underfill encapsulating the plurality of first wires and the plurality of second wires.

11. The package structure of claim 10, wherein the underfill contacts a portion of a lateral surface of one of the plurality of first wires.

12. The package structure of claim 11, wherein the underfill is spaced apart from a gap between the plurality of first wires.

13. The package structure of claim 9, wherein a portion of the first electronic device is vertically non-overlapping with the bridge interposer, and a portion of the second electronic device is vertically non-overlapping with the bridge interposer.

14. The package structure of claim 13, wherein the bridge interposer further includes a plurality of third wires disposed under a gap between the first electronic device and the second electronic device.

15. The package structure of claim 14, wherein the plurality of third wires does not electrically connect the first electronic device and the second electronic device, and the package structure further includes an underfill extending into a gap between the plurality of third wires.

16. The package structure of claim 9, further comprising a wiring structure disposed under the bridge interposer, and the first electronic device is electrically connected to the wiring structure through a solder material.

17. A package structure, comprising:
a wiring structure;
a first electronic device disposed over the wiring structure, and including a first contact, a second contact, a plurality of wires disposed on the first contact and a bump disposed on the second contact; and
a solder material electrically connected to the bump.

18. The package structure of claim 17, further comprising a second electronic device disposed over the wiring structure, wherein the first electronic device is electrically connected to the second electronic device through the plurality of wires, and the first electronic device is electrically connected to the wiring structure through the solder material.

19. The package structure of claim 18, wherein the plurality of wires is closer to the second electronic device than the bump is.

20. The package structure of claim 17, wherein a length of the bump is greater than a length of one of the plurality of wires.
